(19) United States
(12) Patent Application Publication
(10) Pub. No.: US 2024/0312840 A1
(43) Pub. Date: Sep. 19, 2024

(54) THROUGH VIA STRUCTURE AND METHOD OF FABRICATION THEREOF

(71) Applicant: Taiwan Semiconductor Manufacturing Company, Ltd., Hsin-Chu (TW)

(72) Inventors: Lee-Wen Hsu, Hsinchu City (TW); Liang-Wei Wang, Hsinchu City (TW); Chih-Pin Chiu, Hsinchu (TW); Dian-Hau Chen, Hsinchu (TW)

(21) Appl. No.: 18/349,325

(22) Filed: Jul. 10, 2023

Related U.S. Application Data
(60) Provisional application No. 63/490,808, filed on Mar. 17, 2023.

(51) Int. Cl. H01L 21/768; H01L 23/48

(52) U.S. Cl. CPC H01L 21/76898; H01L 23/481

(57) ABSTRACT

Through via structures and methods of fabrication thereof are disclosed herein. An exemplary method includes forming a trench that extends through an insulation layer and into a substrate. The substrate has a first side (e.g., frontside) and a second side (e.g., backside). The insulation layer is disposed over the first side of the substrate. The method includes filling the trench with a dielectric material and performing a thinning process on the second side of the substrate that exposes the dielectric material. After the thinning process and removing the dielectric material from the trench, the method includes forming an electrically conductive structure (e.g., a barrier liner that wraps an electrically conductive plug) in the trench that extends through the substrate from the first side to the second side. A portion of the barrier liner that forms a top of the electrically conductive structure is disposed in the insulation layer.

### PRIORITY DATA

This is a non-provisional application of and claims benefit of U.S. Provisional Patent Application Ser. No. 63/490,808, filed Mar. 17, 2023, the entire disclosure of which is incorporated herein by reference.

### BACKGROUND

Advanced IC packaging technologies have been developed to further reduce density and/or improve performance of integrated circuits (ICs), which are incorporated into many electronic devices. For example, IC packaging has evolved, such that multiple ICs may be vertically stacked in three-dimensional (“3D”) packages or 2.5D packages (e.g., packages that implement an interposer). Through via (also referred to as through-silicon via (TSV)) is one technique for electrically and/or physically connecting stacked ICs and/or chips. Although existing TSV structures and methods of fabrication thereof have been generally adequate for their intended purposes, they have not been entirely satisfactory in all respects as IC feature dimensions, including TSV dimensions, decrease with scaling IC technology nodes.

### BRIEF DESCRIPTION OF THE DRAWINGS

The present disclosure is best understood from the following detailed description when read with the accompanying figures. It is emphasized that, in accordance with standard practice in the industry, various features are not drawn to scale and are used for illustration purposes only. Dimensions of the various features may be arbitrarily increased or reduced for clarity of discussion.

FIG. 1 is a cross-sectional view of a semiconductor structure having an improved through via structure design, such as an improved through silicon via (TSV), in portion or entirety, according to various aspects of the present disclosure.

FIG. 2 is a top view of a semiconductor structure, such as the semiconductor structure of FIG. 1, in portion or entirety, according to various aspects of the present disclosure.

FIG. 3 is a cross-sectional view of a semiconductor arrangement, in portion or entirety, that includes a through via, such as the TSV of the semiconductor structure of FIG. 1 and FIG. 2, according to various aspects of the present disclosure.

FIG. 4 is a cross-sectional view of another semiconductor arrangement, in portion or entirety, that includes a through via, such as the TSV of the semiconductor structure of FIG. 1 and FIG. 2, according to various aspects of the present disclosure.

FIGS. 5A-50 are cross-sectional views of a workpiece, in portion or entirety, at various fabrication stages of forming a through via, such as the TSV of the semiconductor structure of FIG. 1 and FIG. 2, according to various aspects of the present disclosure.

FIGS. 6A-6E are cross-sectional views of a workpiece, in portion or entirety, at various fabrication stages of forming a trench for a through via, which can be implemented at the fabrication stage of FIG. 5E, according to various aspects of the present disclosure.

FIG. 7 is a flow chart of a method, in portion or entirety, for fabricating a through via, the TSV depicted in FIG. 1 and FIG. 2, according to various aspects of the present disclosure.

FIG. 8 is a cross-sectional view of a device substrate, in portion or entirety, that can be implemented in a semiconductor structure, such as the semiconductor structure of FIG. 1 and FIG. 2, according to various aspects of the present disclosure.

### DETAILED DESCRIPTION

The present disclosure relates generally to integrated circuit (IC) packaging, and more particularly, to through vias (also referred to as through-semiconductor vias (TSVs)).

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact and may also include embodiments in which additional features may be formed between the first feature and the second feature, such that the first feature and the second feature may not be in direct contact. In addition, spatially relative terms, for example, “lower,” “upper,” “horizontal,” “vertical,” “above.” “over.” “below.” “beneath,” “up,” “down,” “top,” “bottom,” etc. as well as derivatives thereof (e.g., “horizontally.” “downwardly.” “upwardly.” etc.) are used for ease of the present disclosure to describe one feature's relationship to another feature. The spatially relative terms are intended to cover different orientations of the device including the features.

Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. In another example, two features described as having “substantially the same” dimension and/or “substantially” oriented in a particular direction and/or configuration (e.g., “substantially parallel” or “substantially perpendicular”) encompasses dimension differences between the two features and/or slight orientation variances of the two features from the exact specified orientation that may arise inherently, but not intentionally, from manufacturing tolerances associated with fabricating the two features. Still further, the present disclosure may repeat reference numerals and/or letters in the various examples. This repetition is for the purpose of simplicity and clarity and does not in itself dictate a relationship between the various embodiments and/or configurations described herein.

Advanced IC packaging technologies have been developed to further reduce density and/or improve performance of integrated circuits (ICs), which are incorporated into many electronic devices. For example, IC packaging has evolved, such that multiple ICs can be vertically stacked in three-dimensional (“3D”) packages or 2.5D packages (e.g., packages that implement an interposer). Through via (also referred to as through-silicon via (TSV)) is one technique for electrically and/or physically connecting stacked ICs. For example, where a first chip is stacked vertically over a second chip, a TSV can be formed that extends vertically through the first chip to the second chip. The TSV canelectrically and/or physically connect a first conductive structure (e.g., first wiring) of the first chip to a second conductive structure (e.g., second wiring) of the second chip. The TSV is a conductive structure, such as a copper structure, and may extend through a device substrate of the first chip to the second chip.

A guard ring is often formed around the TSV to protect the TSV, improve TSV performance, improve TSV structural stability, shield and/or reduce TSV-induced noise that can negatively impact the first chip and/or the second chip, or a combination thereof. The guard ring may be formed when forming a back-end-of-line (BEOL) structure of the first chip, such as the first wiring of the first chip. The first wiring may be disposed over and connected to a first device substrate of the first chip and facilitate operation and/or electrical communication of devices and/or structures of the first device substrate. The TSV can be formed after forming the BEOL structure, for example, by etching through a dielectric layer of the BEOL structure in an area defined by the guard ring and into the first device substrate to form a TSV trench, filling the TSV trench with a conductive structure (e.g., a bulk copper layer over a barrier/seed layer), and thinning the first device substrate (e.g., from its backside) to expose the conductive structure (e.g., by a planarization process and/or a grinding process). A topmost metallization layer of the BEOL structure of the first chip can be formed before and/or after the thinning, and the topmost metallization layer can include a top metal layer of the TSV that may be physically and/or electrically connected to the guard ring. In some embodiments, the first chip is attached to the second chip after forming the TSV and the topmost metallization layer.

As IC technology nodes scale, TSV widths (e.g., critical dimensions) may be reduced to reduce footprints of the TSVs (i.e., area overhead) and/or reduce power consumption, while TSV depths/heights may be increased to improve mechanical properties. However, decreasing TSV widths and increasing TSV depths/widths has led to TSV trenches (and thus TSVs) having higher aspect ratios (i.e., depths/heights that are much greater than widths), which has led to undesirable void formation in TSVs. A TSV fabrication technique is thus disclosed that can reduce TSV aspect ratio, thereby improving gap fill and/or reducing void formation in the TSV. The TSV fabrication technique includes etching through a dielectric layer of a BEOL structure (e.g., in an area defined by a guard ring) and into a device substrate to form a TSV trench, filling the TSV trench with a sacrificial material, thinning the device substrate (e.g., from its backside) to expose the dielectric material, removing the dielectric material, and filling the TSV trench with a conductive structure. Filling the trench with the conductive structure can include forming a dielectric liner (e.g., an oxide liner) along sidewalls (e.g., formed by the dielectric layer of the BEOL structure) and a bottom (e.g., formed by a carrier wafer/substrate), forming a barrier/seed layer over the oxide liner, and forming a bulk electrically conductive layer over the barrier/seed layer. In such embodiments, materials of the conductive structure are deposited over a backside of the device substrate, such that a bottom of the trench is disposed in the dielectric layer of the BEOL structure and provides a top of the TSV. Accordingly, a portion of the barrier/seed layer that extends between sidewall portions of the barrier/seed layer forms a top of the TSV and is disposed in the dielectric layer of the BEOL structure. Because the thinning is performed before forming the conductive structure, an aspect ratio of the TSV can be reduced without damaging the TSV, and the dielectric material can prevent change in shape of the TSV trench during the thinning. Reducing the aspect ratio of the TSV trench (and thus the TSV) reduces and/or prevents voids from forming in the TSV and reduces dimensions, area overhead, power consumption, or a combination thereof of the TSV. Details of the proposed TSV structure and/or dimensions and/or fabrication thereof are described herein. Different embodiments may have different advantages, and no particular advantage is required of any embodiment.

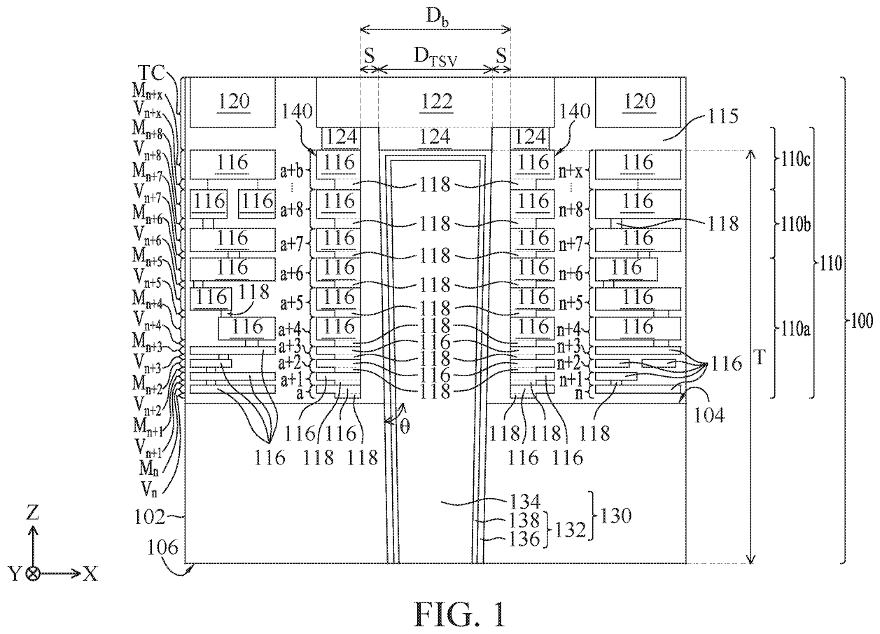

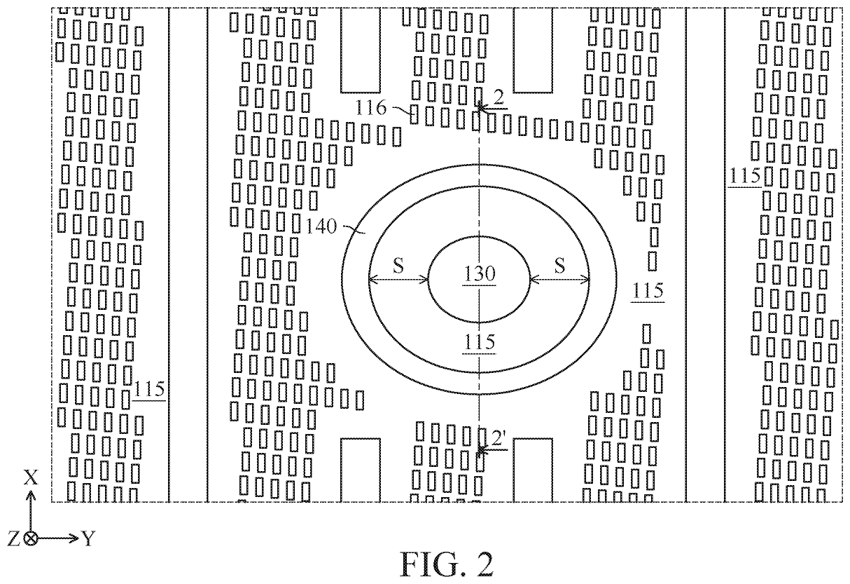

FIG. 1 is a cross-sectional view of a semiconductor structure 100 having an improved through via structure design, such as an improved through silicon via (TSV), in portion or entirety, according to various aspects of the present disclosure. FIG. 2 is a top view of semiconductor structure 100, in portion or entirety, according to various aspects of the present disclosure. The cross-sectional view of FIG. 1 is along line 2-2′ of FIG. 2, and a top contact layer TC of semiconductor structure 100 depicted in FIG. 1 is removed in FIG. 2. FIG. 1 and FIG. 2 are discussed concurrently herein for ease of description and understanding. FIG. 1 and FIG. 2 have been simplified for the sake of clarity to better understand the inventive concepts of the present disclosure. Additional features can be added in semiconductor structure 100 and/or features thereof, and some of the features described below can be replaced, modified, or eliminated in other embodiments of semiconductor structure 100 and/or features thereof.

In FIG. 1, a device substrate 102 is depicted having a side 104 (e.g., a frontside) and a side 106 (e.g., a backside) that is opposite side 104. Device substrate 102 can include circuitry (not shown) fabricated on and/or over side 104 by front end-of-line (FEOL) processing. For example, device substrate 102 can include various device components/features, such as a semiconductor substrate, doped wells (e.g., n-wells and/or p-wells), isolation features (e.g., shallow trench isolation (STI) structures and/or other suitable isolation structures), gates (e.g., a gate stack having a gate electrode and a gate dielectric), gate spacers along sidewalls of the gates, source/drains (e.g., epitaxial source/drains), other suitable device components and/or device features, or a combination thereof. In some embodiments, device substrate 102 includes a planar transistor, where a channel of the planar transistor is formed in the semiconductor substrate between respective source/drains and a respective gate is disposed on the channel (e.g., on a portion of the semiconductor substrate in which the channel is formed). In some embodiments, device substrate 102 includes a non-planar transistor having a channel formed in a semiconductor fin that extends from the semiconductor substrate and between respective source/drains on/in the semiconductor fin, where a respective gate is disposed on and wraps the channel of the semiconductor fin (i.e., the non-planar transistor is a fin-like field effect transistor (FinFET)). In some embodiments, device substrate 102 includes a non-planar transistor having channels formed in semiconductor layers suspended over the semiconductor substrate and extending between respective source/drains, where a respective gate is disposed on and at least partially surrounds the channels (i.e., the non-planar transistor is a gate-all-around (GAA) transistor and/or a fork-sheet transistor). The various transistors of device substrate 102 can be configured as planar transistors or non-planar transistors depending on design requirements.

Device substrate 102 can include various passive electronic devices and active electronic devices, such as resistors, capacitors, inductors, diodes, p-type FETs (PFETs), n-type FETs (NFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable components, or a combination thereof. The various electronic devices can be configured to provide functionally distinct regions of an IC, such as a logic region (i.e., a core region), a memory region, an analog region, a peripheral region (e.g., an input/output (I/O) region), a dummy region, other suitable region, or a combination thereof. The logic region may be configured with standard cells, each of which can provide a logic device and/or a logic function, such as an inverter, an AND gate, an NAND gate, an OR gate, an NOR gate, a NOT gate, an XOR gate, an XNOR gate, other suitable logic device, or a combination thereof. The memory region may be configured with memory cells, each of which can provide a storage device and/or storage function, such as flash memory, non-volatile random-access memory (NVRAM), static random-access memory (SRAM), dynamic random-access memory (DRAM), other volatile memory, other non-volatile memory, other suitable memory, or a combination thereof. In some embodiments, memory cells and/or logic cells include transistors and interconnect structures that combine to provide storage devices/functions and logic devices/functions, respectively, of a chip.

A multi-layer interconnect (MLI) feature 110 is disposed over side 104 of device substrate 102. MLI feature 110 electrically connects various devices (e.g., transistors) and/or components of device substrate 102 and/or various devices (e.g., a memory device disposed within MLI feature 110) and/or components of MLI feature 110, such that the various devices and/or components can operate as specified by design requirements. MLI feature 110 includes a combination of dielectric layers and electrically conductive layers (e.g., patterned metal layers) configured to form interconnect (routing) structures. The conductive layers form vertical interconnect structures, such as device-level contacts and/or vias, and/or horizontal interconnect structures, such as conductive lines. Vertical interconnect structures typically connect horizontal interconnect structures in different layers/levels (or different planes) of MLI feature 110. During operation, the interconnect structures can route electrical signals between devices and/or components of device substrate 102 and/or MLI feature 110 and/or distribute electrical signals (for example, clock signals, voltage signals, ground signals, etc.) to the devices and/or the device components of device substrate 102 and/or MLI feature 110. Though MLI feature 110 is depicted with a given number of dielectric layers and metal layers, the present disclosure contemplates MLI feature 110 having more or less dielectric layers and/or metal layers.

MLI feature 110 can include circuitry fabricated on and/or over side 104 by back end-of-line (BEOL) processing and thus can also be referred to as a BEOL structure. MLI feature 110 includes an n level interconnect layer, an (n+x) level interconnect layer, and intermediate interconnect layer(s) therebetween (i.e., an (n+1) level interconnect layer, an (n+2) level interconnect layer, and so on), where n is an integer greater than or equal to 1 and x is an integer greater than or equal to 1. Each of n level interconnect layer to (n+x) level interconnect layer includes a respective metallization layer and a respective via layer. For example, n level interconnect layer includes a respective n via layer (denoted as Vₙ) and a respective n metallization layer (denoted as Mₙ) over n via layer, (n+1) level interconnect layer includes a respective (n+1) via layer (denoted as Vₙ₊₁) and a respective (n+1) metallization layer (denoted as Mₙ₊₁) over (n+1) via layer, and so on for the intermediate layers to (n+x) level interconnect layer, which includes a respective (n+x) via layer (denoted as Vₙ₊ₓ) and an (n+x) metallization layer (denoted as Mₙ₊ₓ) over (n+x) via layer. In the depicted embodiment, n equals 1, x equals 9, and MLI feature 110 includes ten interconnect layers, such as a 1^{st} level interconnect layer including a V₁ layer and an M₁ layer, a 2^{nd} level interconnect layer including a V₂ layer and an M₂ layer, and so on to a 10^{th} level interconnect layer including a V₁₀ layer and an M₁₀ layer. Each via layer physically and/or electrically connects an underlying metallization layer and an overlying metallization layer, an underlying device-level contact layer (e.g., a middle end-of-line (MEOL) interconnect layer, such as an M₀ layer) and an overlying metallization layer, an underlying device feature (e.g., a gate electrode of a gate or a source/drain) and an overlying metallization layer, or an underlying metallization layer and an overlying top contact layer. For example, V₂ layer is between, physically connected, and electrically connected to M₁ layer and M₂ layer. In another example, V₁ layer is between, physically connected, and electrically connected to M₁ layer and an underlying device-level contact layer and/or an underlying device feature. In some embodiments, the metallization layers and the via layers are further electrically connected to device substrate 102. For example, a first combination of metallization layers and via layers are electrically connected to a gate of a transistor of device substrate 102 and a second combination of metallization layers and via layers are electrically connected to a source/drain of the transistor, such that voltages can be applied to the gate and/or the source/drain.

MLI feature 110 includes a insulation layer 115 having metal lines 116, vias 118, other conductive features, or combinations thereof disposed therein. Each of Mₙ metallization layer to Mₙ₊ₓ metallization layer includes a patterned metal layer (i.e., a group of metal lines 116 arranged in a desired pattern) in a respective portion of insulation layer 115. Each of Vₙ via layer to Vₙ₊ₓ via layer includes a patterned metal layer (i.e., a group of vias 118 arranged in a desired pattern) in a respective portion of insulation layer 115. Insulation layer 115 includes a dielectric material, such as silicon oxide, tetraethylorthosilicate (TEOS) oxide, phosphosilicate glass (PSG), boron-doped silicate glass (BSG), boron-doped PSG (BPSG), low-k dielectric material (having, for example, a dielectric constant that is less than a dielectric constant of silicon oxide (e.g., k<3.9)), other suitable dielectric material, or a combination thereof. Exemplary low-k dielectric materials include fluorosilicate glass (FSG), carbon-doped oxide, Black Diamond® (Applied Materials of Santa Clara, California), xerogel, aerogel, amorphous fluorinated carbon, parylene, benzocyclobutene (BCB), SiLK (Dow Chemical, Midland, Michigan), polyimide, other low-k dielectric material, or a combination thereof. In some embodiments, insulation layer 115 includes a low-k dielectric material, such as carbon-doped oxide, or an extreme low-k dielectric material (e.g., k≤2.5), such as porous carbon-doped oxide.

Insulation layer 115 has a multilayer structure. For example, insulation layer 115 can include at least one interlevel dielectric (ILD) layer, at least one contact etch stop layer (CESL) disposed between respective ILD layers, and at least one CESL disposed between a respective ILD layer and device substrate 102. In such embodiments, a material of the CESL is different than a material of the ILD layer. For example, where the ILD layer includes a low-k dielectric material that includes silicon and oxygen, the CESL can include silicon and nitrogen (e.g., silicon nitride, silicon oxynitride, silicon carbonitride, or a combination thereof) or other suitable dielectric material. The ILD layer and/or the CESL may have a multilayer structure having multiple dielectric materials. In some embodiments, each of n level interconnect layer to (n+x) level interconnect layer includes a respective ILD layer and/or a respective CESL of insulation layer 115, and respective metal lines 116 and vias 118 are in the respective ILD layer and/or the respective CESL. In some embodiments, each of Mₙ layer to Mₙ₊ₓ layer includes a respective ILD layer and/or a respective CESL of insulation layer 115, where respective metal lines 116 are in the respective ILD layer and/or the respective CESL. In some embodiments, each of Vₙ layer to Vₙ₊ₓ layer includes a respective ILD layer and/or a respective CESL of insulation layer 115, where respective vias 118 are in the respective ILD layer and/or the respective CESL.

A top contact (TC) layer is disposed over MLI feature 110, and in the depicted embodiment, is disposed over a topmost metallization layer of MLI feature 110 (i.e., M₁₀ layer). TC layer includes patterned metal layers (i.e., a group of contacts 120 and a contact 122 arranged in a desired pattern (e.g., a contact layer) and a group of vias 124 arranged in a desired pattern (e.g., a via layer)) in a respective portion of insulation layer 115. The via layer (e.g., vias 124) physically and/or electrically connects the contact layer (e.g., contacts 120 and contact 122) to MLI feature 110 (e.g., metal lines 116 of Mₙ₊ₓ layer). Contacts 120 and/or contact 122 may facilitate electrical connection of MLI feature 110 and/or device substrate 102 to external circuitry and thus may be referred to as external contacts. In some embodiments, contacts 120 and/or contact 122 are under-bump metallization (UBM) structures. In some embodiments, insulation layer 115 includes at least one passivation layer. For example, insulation layer 115 may include a passivation layer disposed over a topmost metallization layer of MLI feature 110, such as M₁₀ layer. In such embodiments, TC layer may include the passivation layer, where contacts 120, contact 122, and vias 124 are disposed in the passivation layer. The passivation layer includes a material that is different than a dielectric material of an underlying ILD layer of MLI feature 110. In some embodiments, the passivation layer includes polyimide, undoped silicate glass (USG), silicon oxide, silicon nitride, other suitable passivation material, or a combination thereof. In some embodiments, a dielectric constant of a dielectric material of the passivation layer is greater than a dielectric constant of a topmost ILD layer of MLI feature 110. The passivation layer may have a multilayer structure having multiple dielectric materials. For example, the passivation layer can include a silicon nitride layer and a USG layer.

Metal lines 116, vias 118, contacts 120, contact 122, and vias 124 include a metal material, including for example, aluminum, copper, titanium, tantalum, tungsten, ruthenium, cobalt, iridium, palladium, platinum, nickel, tin, gold, silver, other suitable metals, alloys thereof, silicides thereof, or a combination thereof. In some embodiments, metal lines 116, vias 118, contacts 120, contact 122, vias 124, or a combination thereof include a bulk metal layer (also referred to as a metal fill layer, a conductive plug, a metal plug, etc.). In some embodiments, metal lines 116, vias 118, contacts 120, contact 122, vias 124, or a combination thereof include a barrier layer, an adhesion layer, other suitable layer, or a combination thereof disposed between the bulk metal layer and insulation layer 115. The barrier layer can include titanium, titanium alloy (e.g., TiN), tantalum, tantalum alloy (e.g., TaN), other suitable barrier material (e.g., a material that can prevent diffusion of metal constituents from metal lines 116, vias 118, contacts 120, contact 122, vias 124, or a combination thereof into a surrounding dielectric, such as insulation layer 115), or a combination thereof. In some embodiments, metal lines 116, vias 118, contacts 120, contact 122, vias 124, or a combination thereof include different metal materials. For example, lower metal lines 116 and/or vias 118 of MLI feature 110 include tungsten, ruthenium, cobalt, or a combination thereof, while higher metal lines 116 and/or vias 118 of MLI feature 110 include copper. In some embodiments, metal lines 116, vias 118, contacts 120, contact 122, vias 124, or a combination thereof include the same metal materials.

Each metallization layer is a patterned metal layer having metal lines 116, where the patterned metal layer has a corresponding pitch. Metallization layers of MLI feature 110 can thus be grouped by their respective pitches. A pitch of a patterned metal layer generally refers to a sum of a width of metal lines (e.g., metal lines 116) of the patterned metal layer and a spacing between directly adjacent metal lines of the patterned metal layer (i.e., a lateral distance between edges of directly adjacent metal lines 116 of the patterned metal layer). In some embodiments, a pitch of the patterned metal layer is a lateral distance between centers of directly adjacent metal lines 116 of the patterned metal layer. In FIG. 1, metallization layers having a same pitch are grouped together. For example, MLI feature 110 has a set 110a of metallization layers having a pitch P1, a set 110b of metallization layers having a pitch P2, and a set 110c of metallization layers having a pitch P3. Set 110a includes M₁ layer through M₇ layer, set 110B includes M₈ layer and M₉ layer, and set 110c includes M₁₀ layer. Pitch P1, pitch P2, and pitch P3 are different. In the depicted embodiment, pitch P1 is less than pitch P2, and pitch P2 is less than pitch P3. In such embodiments, pitch of metallization layers of MLI feature 110 increases as distance increases between the metallization layers and front side 104 of device substrate 102. In some embodiments, pitch P1 is greater than pitch P2, and pitch P2 is greater than pitch P3. In some embodiments, pitch P1 is greater than pitch P2 and less than pitch P3. In some embodiments, pitch P1 is less than pitch P2 and greater than pitch P3. MLI feature 110 can include any number of metallization layer sets (groups) having different pitches depending on IC technology node and/or IC generation (e.g., 20 nm, 5 nm, etc.). In some embodiments, MLI feature 110 includes three sets to six sets of metallization layers having different pitches.

A through substrate via (TSV) 130 (also referred to as a through silicon via or a through semiconductor via) is disposed in insulation layer 115. TSV 130 is physically and/or electrically connected to TC layer (e.g., a respective via 124 physically and electrically connects TSV to contact 122, which is connected to a guard ring 140). TSV 130 extends from contact 122, through insulation layer 115, and through device substrate 102. In FIG. 1, TSV 130 extends from side 104 to side 106 of device substrate 102, such that TSV 130 extends entirely through device substrate 102. TSV 130 has a dimension D_{TSV}, such as a width or a diameter, along the x-direction. Dimension D_{TSV} can also be referred to as a critical dimension (CD) of TSV 130. In some embodiments, dimension D_{TSV} is about 1 μm to about 18 μm. In FIG. 2, TSV 130 has a circular shape in a top view, and dimension D_{TSV} represents a diameter of TSV 130. In such embodiments, TSV 130 may be a cylindrical structure that extends through insulation layer 115. TSV 130 may have different shapes in a top view, such as a square shape, a rhombus shape, a trapezoidal shape, a hexagonal shape, an octagonal shape, or other suitable shape.

In some embodiments, TSV 130 has a substantially vertical sidewall profile, and dimension D_{TSV} is substantially the same along a thickness T of TSV 130 (e.g., along the z-direction). In such embodiments, dimension D_{TSV} at a top of TSV 130 (e.g., a portion thereof interfacing with contact 122), dimension D_{TSV} at a middle of TSV 130 (e.g., a portion thereof at an interface of insulation layer 115 and device substrate 102), and dimension D_{TSV} at a bottom of TSV 130 (e.g., a portion thereof at side 106 of device substrate 102) are substantially the same. For example, a ratio of a top CD of TSV 130 (i.e., dimension D_{TSV} at a top of TSV 130) to a middle CD of TSV 130 (i.e., dimension D_{TSV} at a middle of TSV 130) to a bottom CD of TSV 130 (i.e., dimension D_{TSV} at a bottom of TSV 130) is about 1:1:1. In some embodiments, dimension D_{TSV} varies along thickness T. For example, in the depicted embodiment, TSV 130 has a tapered sidewall profile (i.e., tapered sidewalls), and dimension D_{TSV} decreases from a top of TSV 130 to a bottom of TSV 130. In such embodiments, a ratio of a top CD to a middle CD to a bottom CD (top CD:middle CD:bottom CD) can be about 1:1:1 to about 4:2:1. In some embodiments, TSV 130 has a tapered sidewall profile, and dimension D_{TSV} increases from a top of TSV 130 to a bottom of TSV 130. In such embodiments, a ratio of the top CD to the middle CD to the bottom CD can be about 1:1:1 to about 1:2:4. In some embodiments, the top CD is greater than or less than the bottom CD. In some embodiments, dimension D_{TSV} can be substantially uniform along thickness T at portions of TSV 130, such as in device substrate 102 or insulation layer 115. The present disclosure contemplates TSV 130 having any variation of dimension D_{TSV} along its thickness T depending on its sidewall profile configuration.

An aspect ratio of TSV 130 is given by a ratio of thickness T to dimension D_{TSV} (e.g., thickness T/dimension D_{TSV}). In some embodiments, TSV 130 has an aspect ratio of about 1 to about 20. An angle θ is between sidewalls of TSV 130 and a top surface of device substrate 102 (i.e., side 104 thereof). In some embodiments, angle θ is about 70° to about 95°. In the depicted embodiment, angle θ is with respect to the x-axis, which is substantially parallel with the top surface of device substrate 102. If angle θ is too small (e.g., less than 70°), a width of an opening in which TSV 130 is formed may be too narrow and result in pinch off during gap fill (i.e., filling of the opening with bulk layer 134) that can lead to void formation in TSV 130. On the other hand, if angle θ is too large (e.g., greater than 95°), a spacing between TSV 130 and guard ring 140 may be too small, which can lead to damage of guard ring 140 during fabrication of TSV 130. In some embodiments, if angle θ is too large, TSV 130 may increase effective resistance and/or reduce capacitance, which can degrade device performance. In some embodiments, if angle θ is too large, TSV 130 spans a larger are of device substrate 102, which may undesirable reduce an area for forming device features of device substrate 102.

TSV 130 includes an electrically conductive material, including for example, aluminum, copper, titanium, tantalum, tungsten, ruthenium, cobalt, iridium, palladium, platinum, nickel, tin, gold, silver, other suitable metals, alloys thereof, silicides thereof, or a combination thereof. In FIG. 1. TSV 130 has a multilayer structure. For example, TSV 130 includes a barrier layer 132 and a bulk layer 134 (also referred to as a metal fill layer, a conductive plug, a metal plug, etc.). Barrier layer 132 wraps bulk layer 134, and because TSV 130 is fabricated as described herein, barrier layer 132 is disposed along a top, instead of a bottom, and sidewalls of bulk layer 134 (and thus along the top/frontside, not the bottom/backside, and sidewalls of TSV 130). Further, barrier layer 132 is disposed between bulk layer 130 and TC layer (e.g., via 124), barrier layer 132 is disposed between bulk layer 134 and insulation layer 115, and barrier layer 132 is disposed between bulk layer 134 and device substrate 102.

In FIG. 1, barrier layer 132 includes a dielectric liner 132 and a barrier/seed liner 138. Dielectric liner 132 is disposed between barrier/seed liner 138 and TC layer (e.g., via 124), dielectric liner 132 is disposed between barrier/seed liner 138 and insulation layer 115, and dielectric liner 132 is disposed between barrier/seed liner 138 and device substrate 102. Dielectric liner 132 includes a dielectric material, such as silicon oxide, silicon nitride, other suitable dielectric material, or a combination thereof. In the depicted embodiment, dielectric liner 132 includes oxygen and can be referred to as an oxide liner. Barrier/seed liner 138 can include titanium, titanium alloy (e.g., TiN and/or TiC), tantalum, tantalum alloy (e.g., TaN and/or TaC), aluminum, aluminum alloy (e.g., AlON and/or Al₂O₃), silicon (e.g., SiO₂), other suitable barrier/seed material (e.g., a material that can prevent diffusion of metal constituents from bulk layer 134 into insulation layer 115 and/or a material that can facilitate growth and/or deposition of bulk layer 134), or a combination thereof. Bulk layer 134 includes an electrically conductive material, such as aluminum, copper, titanium, tantalum, tungsten, ruthenium, cobalt, iridium, palladium, platinum, nickel, tin, gold, silver, other suitable metals, alloys thereof, silicides thereof, or a combination thereof. In some embodiments, bulk layer 134 includes copper (i.e., TSV 130 includes a copper plug), tungsten (i.e., TSV 130 includes a tungsten plug), or polysilicon (i.e., TSV 130 includes a polysilicon plug). Bulk layer 134, dielectric liner 132, barrier/seed layer 136, or a combination thereof may have a multilayer structure.

Guard ring 140 is disposed in insulation layer 115 and around TSV 130. Guard ring 140 extends through insulation layer 115 from TC layer to side 104 of device substrate 102. A spacing S (also referred to as a distance) is along the x-direction between guard ring 140 and TSV 130, and insulation layer 115 fills spacing S between guard ring 140 and TSV 130. Guard ring 140 has a dimension D_{b}, such as a width or a diameter, along the x-direction. A ratio of dimension D_{b} to dimension D_{TSV} can be configured to optimize spacing S. In some embodiments, the ratio of dimension D_{b} to dimension D_{TSV} is greater than zero and less than about two (i.e., 2>D_{b}/D_{TSV}>0). From a top view (FIG. 2), guard ring 140 is a circular ring around TSV 130, and guard ring 140 extends continuously around TSV 130. In such embodiments, dimension D_{b} represents an inner diameter of guard ring 140. In some embodiments, guard ring 140 has other shapes in a top view. For example, guard ring 140 may be a square ring, a hexagonal ring, an octagonal ring, or other suitable shaped ring. In some embodiments, guard ring 140 is discontinuous (e.g., a ring formed from discrete segments).

Guard ring 140 is physically and/or electrically connected to TC layer (e.g., vias 124 physically and electrically connect guard ring 140 to contact 122). Guard ring 140 may be physically and/or electrically connected to device substrate 102. For example, an MEOL layer (i.e., device-level contacts and/or vias) can physically and/or electrically connect guard ring 140 to device substrate 102, such as to a doped region (e.g., an n-well and/or a p-well) in device substrate 102. In some embodiments, guard ring 140 is electrically connected to a voltage. In some embodiments, guard ring 140 is electrically connected to an electrical ground. In some embodiments, guard ring 140 is configured to electrically insulate TSV 130 from MLI feature 110, device substrate 102, other device features and/or device components, or a combination thereof. In some embodiments, guard ring 140 absorbs thermal stress and/or mechanical stress from, within, and/or around TSV 130. In some embodiments, guard ring 140 reduces thermal stress and/or mechanical stress from, within, and/or around TSV 130. Such stresses can result from TSV 130, device substrate 102, and/or insulation layer 115 having different coefficients of thermal expansion (CTE). Such stresses may result during and/or after fabrication of TSV 130. In some embodiments, guard ring 140 reduces or eliminates cracks at an interface of TSV 130 and device substrate 102 (e.g., at metal/semiconductor interfaces), which may arise from the stresses described herein. In some embodiments, guard ring 140 provides structural support, integrity, reinforcement, or a combination thereof for TSV 130.

Guard ring 140 is fabricated in conjunction with MLI feature 110, and guard ring 140 may be considered a portion of MLI feature 110. For example, guard ring 140 includes a stack of interconnect structures, where the interconnect structures are vertically stacked along the z-direction (or along a thickness direction of TSV 130). Each interconnect structure includes a respective metal line 116 and a respective via 118. In FIG. 1, the stack of interconnect structures includes an a interconnect structure, an (a+b) interconnect structure, and intermediate interconnect structure(s) therebetween (i.e., an (a+1) interconnect structure, an (a+2) interconnect structure, and so on), where a is an integer greater than or equal to 1 and b is an integer greater than or equal to 1. In the depicted embodiment, a is equal to n (e.g., a=1), b is equal to z (e.g., b=9), and guard ring 140 has an interconnect structure that corresponds with each level interconnect layer of MLI feature 110. For example, a interconnect structure forms a conductive ring around TSV 130 in n level interconnect layer, (a+1) interconnect structure forms a conductive ring around TSV 130 in (n+1) level interconnect layer, and so on for the intermediate interconnect structures, and (a+b) interconnect structure forms a conductive ring around TSV 130 in (n+x) level interconnect layer. The present disclosure contemplates guard ring 140 having a number of interconnect structures that is more or less than a number of levels of interconnect layers of MLI feature 110. For example, guard ring 140 may extend from (n+x) level interconnect layer to (n+5) interconnect layer of MLI feature 110.

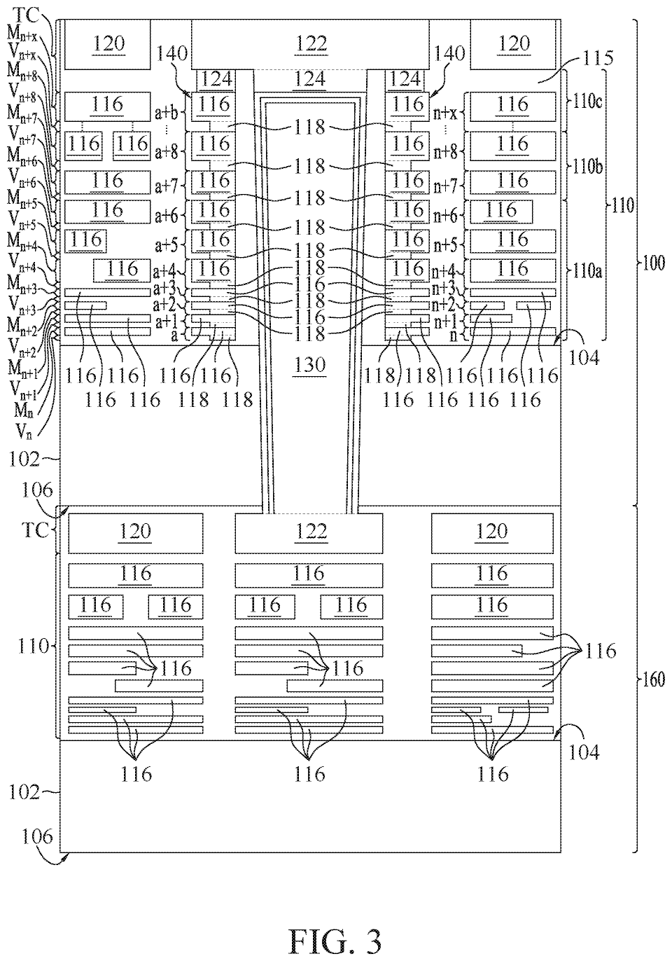

Semiconductor structure 100 may be attached (bonded) to another semiconductor structure to form an IC package or portion thereof. For example, FIG. 3 is a cross-sectional view of a semiconductor arrangement, in portion or entirety, that includes a through via, such as TSV 130, according to various aspects of the present disclosure. In FIG. 3, semiconductor structure 100 is attached to a semiconductor structure 160, which may be similar to semiconductor structure 100. For example, semiconductor structure 160 includes a respective device substrate 102, a respective MLI feature 110 (having respective insulation layer 115, respective metal lines 116, and respective vias 118) disposed over side 104 of the respective device substrate 102, and a respective TC layer (having respective contacts 120) disposed over the respective MLI feature 110. In such embodiments, side 106 (e.g., backside) of device substrate 102 of semiconductor structure 100 is attached to insulation layer 115 of semiconductor structure 160, and TSV 130 of semiconductor structure 100 is connected to a respective contact 122 of TC layer of semiconductor structure 160. TSV 130 electrically and/or physically connects semiconductor structure 100 and semiconductor structure 160. In some embodiments, a bonding layer is in insulation layer 115 of semiconductor structure 160 and between TSV 130 and contact 122 of TC layer of semiconductor structure 160. Semiconductor structure 100 and semiconductor structure 160 may be attached by dielectric-to-dielectric bonding (e.g., oxide-to-oxide bonding), metal-to-metal bonding (e.g., copper-to-copper bonding), metal-to-dielectric bonding (e.g., copper-to-oxide bonding), other type of bonding, or combinations thereof. FIG. 3 has been simplified for the sake of clarity to better understand the inventive concepts of the present disclosure. Additional features can be added in the semiconductor arrangement and/or features thereof, and some of the features described below can be replaced, modified, or eliminated in other embodiments of the semiconductor arrangement and/or features thereof.

In some embodiments, semiconductor structure 100 and semiconductor structure 160 are chips that include at least one functional IC, such as an IC configured to perform a logic function, a memory function, a digital function, an analog function, a mixed signal function, a radio frequency (RF) function, an input/output (I/O) function, a communications function, a power management function, other function, or a combination thereof. In such embodiments, TSV 130 can vertically physically and/or electrically connect chips. In some embodiments, semiconductor structure 100 and semiconductor structure 160 are chips that provide the same function (e.g., central processing unit (CPU)). In some embodiments, semiconductor structure 100 and semiconductor structure 160 are chips that provide different functions (e.g., CPU and graphics processing unit (GPU), respectively). In some embodiments, semiconductor structure 100 and/or semiconductor structure 160 is a system-on-chip (SoC), which generally refers to a single chip or monolithic die having multiple functions. In such embodiments, TSV 130 can vertically physically and/or electrically connect SoCs. In some embodiments, the SoC is a single chip having an entire system, such as a computer system, fabricated thereon.

In some embodiments, semiconductor structure 100 is a portion of a chip-on-wafer-on-substrate (CoWoS) package, an integrated-fan-out (InFO) package, a system on integrated chip (SoIC) package, other three-dimensional integrated circuit (3DIC) package, or a hybrid package that implements a combination of multichip packaging technologies. In some embodiments, TSV 130 of semiconductor structure 100 is physically and/or electrically connected to a package substrate, an interposer, a redistribution layer (RDL), a printed circuit board (PCB), a printed wiring board, other packaging structure and/or substrate, or a combination thereof. In some embodiments, TSV 130 of semiconductor structure 100 is physically and/or electrically connected to controlled collapse chip connections (C4 bonds) (e.g., solder bumps and/or solder balls) and/or microbumps (also referred to as microbonds, μbumps, and/or μbonds), which are physically and/or electrically connected to a packaging structure.

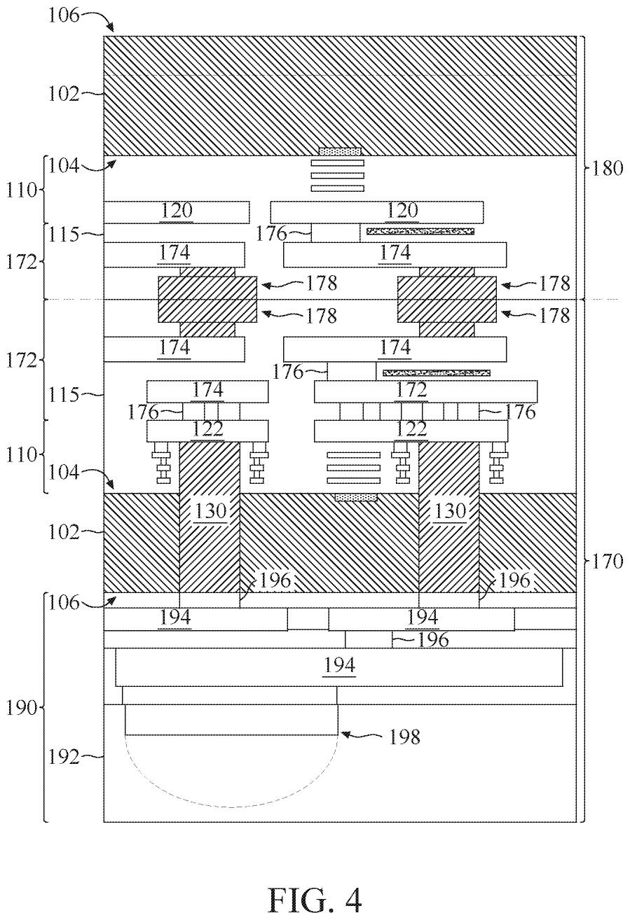

FIG. 4 is a cross-sectional view of another semiconductor arrangement, in portion or entirety, that includes a through via, such as TSV 130, according to various aspects of the present disclosure. In FIG. 4, a frontside and a backside of a semiconductor structure, such a semiconductor structure 170 may be attached (bonded) to respective semiconductor structures to form an IC package or portion thereof. Semiconductor structure 170 is similar to semiconductor structure 100. For example, semiconductor structure 170 has a respective device substrate 102 having side 104 and side 106, a respective MLI feature 110 (having respective insulation layer 115, respective metal lines 116, respective vias 118, and respective guard rings 140) disposed over side 104 of the respective device substrate 102, respective TSVs 130 that extend through insulation layer 115 and device substrate 102, and a respective TC layer (having respective contacts 120 and/or contacts 122) disposed over the respective MLI feature 110. Semiconductor structure 170 further includes a top/frontside interconnect feature 172 disposed over its respective MLI feature 110. Top/frontside interconnect feature 172 can have an insulation layer (e.g., insulation layer 115) and metal lines 174, vias 176, and bonding structures 178 (e.g., single bonding layers and/or a combination of bonding layers/structures, such as a bonding via and a bonding metal line) disposed in the insulation layer. In some embodiments, one or more of metal lines 174 are metal pads, such as aluminum pads. In some embodiments, the insulation layer includes one or more passivation layers and/or various dielectric layers. FIG. 4 has been simplified for the sake of clarity to better understand the inventive concepts of the present disclosure. Additional features can be added in the semiconductor arrangement and/or features thereof, and some of the features described below can be replaced, modified, or eliminated in other embodiments of the semiconductor arrangement and/or features thereof.

In such embodiments, a backside of semiconductor structure 170 is formed by side 106 of device substrate 102 and a frontside of semiconductor structure 170 is formed by top/frontside interconnect feature 172 (here, bonding structures 178 and insulation layer 115). In FIG. 4, the frontside of semiconductor structure 170 is attached to a semiconductor structure 180, which may be similar to semiconductor structure 170. For example, semiconductor structure 180 includes a respective device substrate 102, a respective MLI feature 110 (having respective insulation layer 115, respective metal lines 116, and respective vias 118) disposed over side 104 of the respective device substrate 102, a respective TC layer (having respective contacts 120) disposed over the respective MLI feature 110, and a respective top/frontside interconnect feature 172 (having respective metal lines 174, respective vias 176, and respective bonding structures 178), where the respective top/frontside interconnect feature 172 forms a top/frontside of semiconductor structure 180. Frontside of semiconductor structure 170 is thus attached to frontside of semiconductor structure 180, and semiconductor structure 170 and semiconductor structure 180 are physically and/or electrically connected by bonding structures 178. Further, TSVs 130 of semiconductor structure 170 can be connected to semiconductor structure 180 by TC layer and top/frontside interconnect feature 172 of semiconductor structure 170. TSVs 130 may thus be electrically connected to semiconductor structure 180. In some embodiments, devices at side 104 of semiconductor structure 170 are electrically connected to devices at side 104 of semiconductor structure 180 by MLI features 110 and/or top/frontside interconnect features 172 thereof. Semiconductor structure 170 and semiconductor structure 180 may be attached by dielectric-to-dielectric bonding (e.g., oxide-to-oxide bonding), metal-to-metal bonding (e.g., copper-to-copper bonding), metal-to-dielectric bonding (e.g., copper-to-oxide bonding), other type of bonding, or a combination thereof. In some embodiments, semiconductor structure 170 and semiconductor structure 180 are chips that include at least one functional IC. The chips may be the same or different types. In some embodiments, semiconductor structure 170 and semiconductor structure 180 are logic chips.

In some embodiments, semiconductor 170 further includes a bottom/backside interconnect feature 190 disposed over side 106 of device substrate 102. Bottom/backside interconnect feature 190 can include an insulation layer 192, similar to insulation layer 115 and/or portion thereof forming top/frontside interconnect feature 172, and metal lines 194, vias 196, and under-bump metallization (UBM) features 198 disposed in insulation layer 192. In FIG. 4. TSVs 130 of semiconductor structure 170 are physically and/or electrically connected to bottom/backside interconnect feature 190, which may be connected to external circuitry. In some embodiments, insulation layer 192 includes one or more passivation layers and/or various dielectric layers. In some embodiments, one or more of metal lines 194 are metal pads, such as aluminum pads. In some embodiments, UBM feature 198 can provide low resistance electrical connections to semiconductor structure 170. In some embodiments, UBM feature 198 includes multiple layers of different metals, such as an adhesion layer (e.g., Ti, Cr, Al, other metal, or combinations thereof), a diffusion barrier layer (e.g., CrCu alloy and/or other suitable metal(s)), a solderable layer, and an oxidation barrier layer (e.g., Au and/or other suitable metal(s)). Various layers of UBM feature 198 can be deposited by electroplating, sputtering, evaporation, other method, or combinations thereof. In some embodiments, bottom/backside interconnect feature 190 is or forms a portion of a redistribution layer (RDL) and/or redistribution structure that includes various metal lines for redistributing bonding pads to different locations, such as from peripheral locations to locations uniformly distributed on a chip surface. In some embodiments, the RDL may couple semiconductor structure 170 to the bonding pads for connection to external circuitry and/or another semiconductor structure.

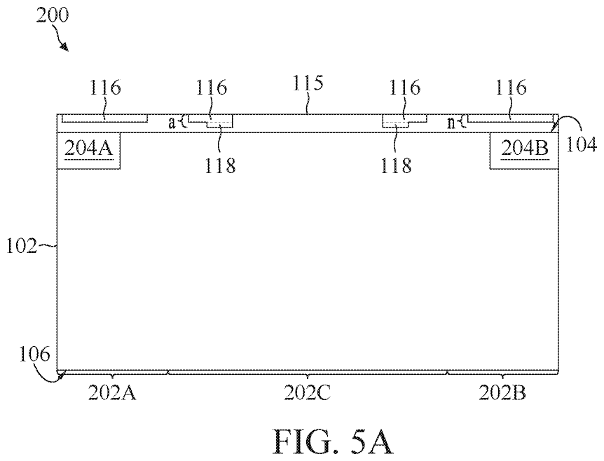

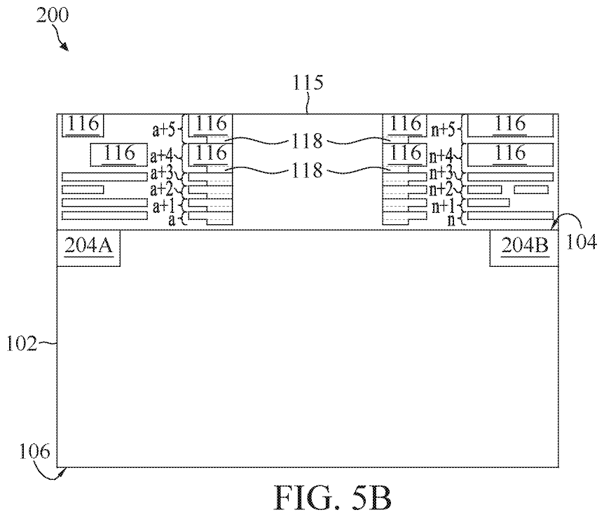

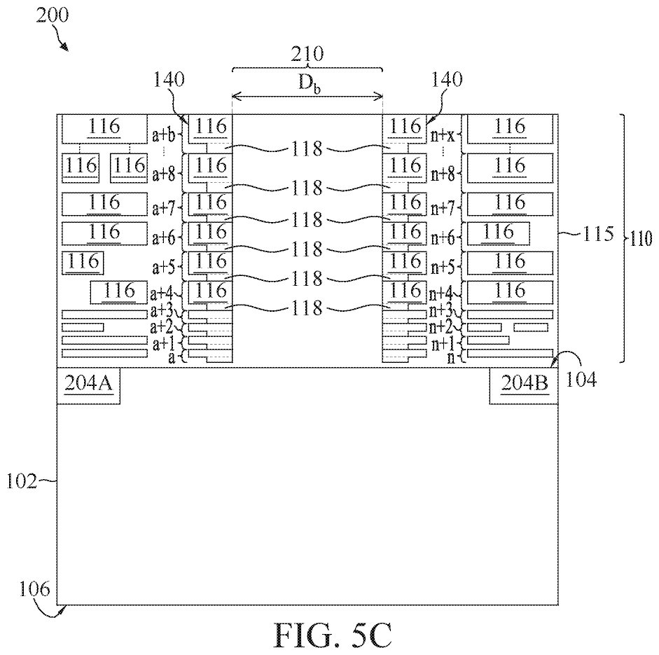

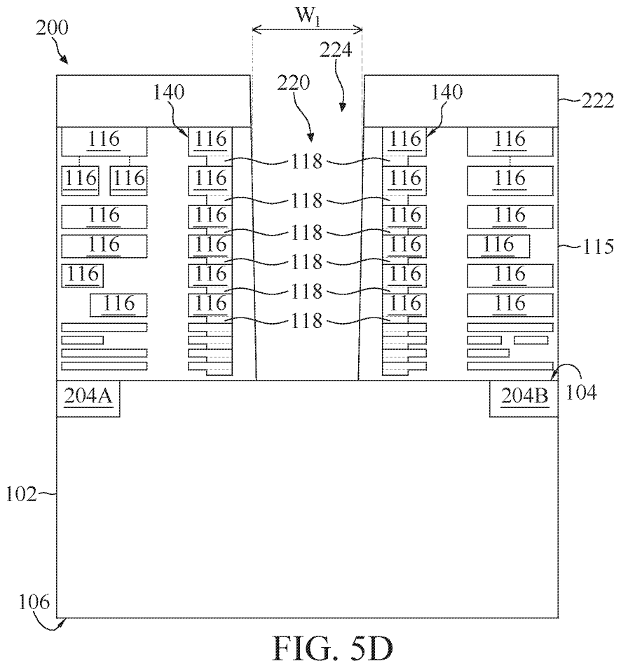

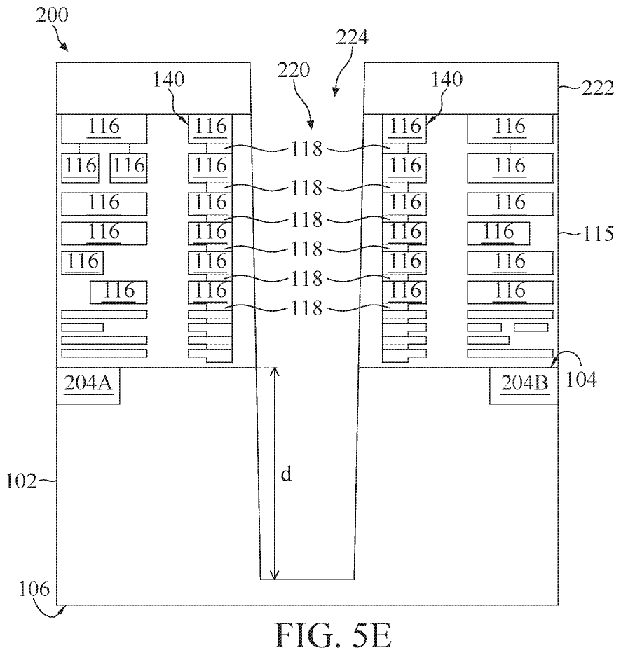

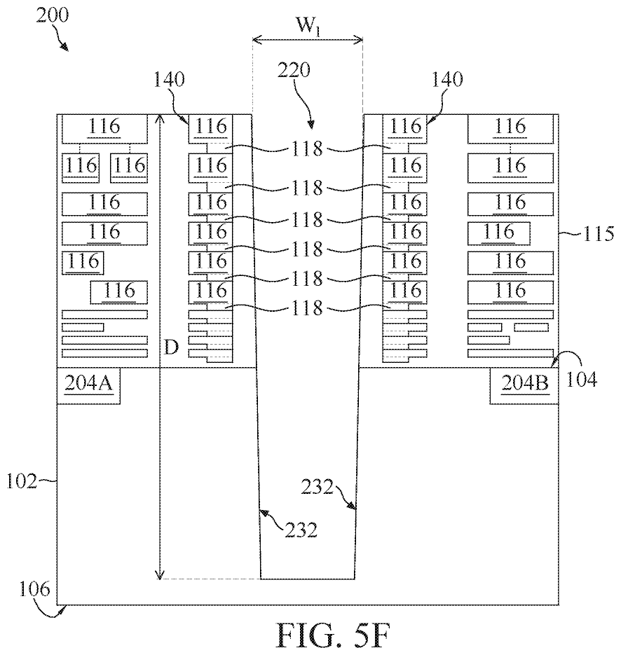

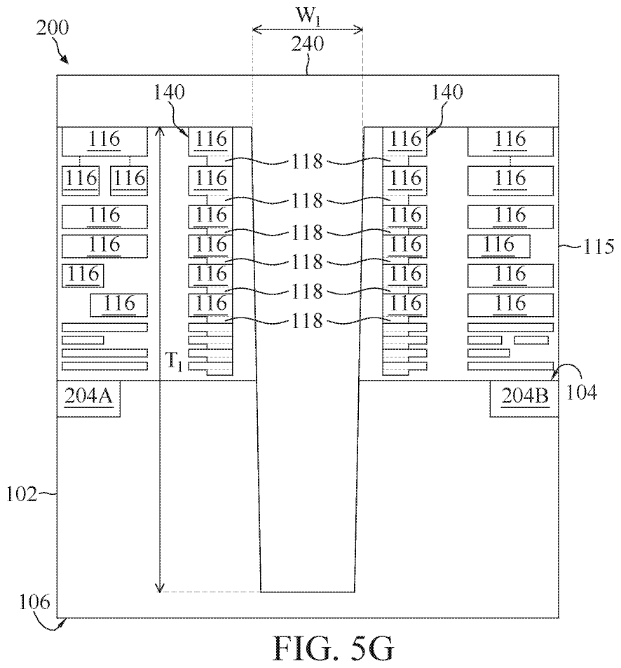

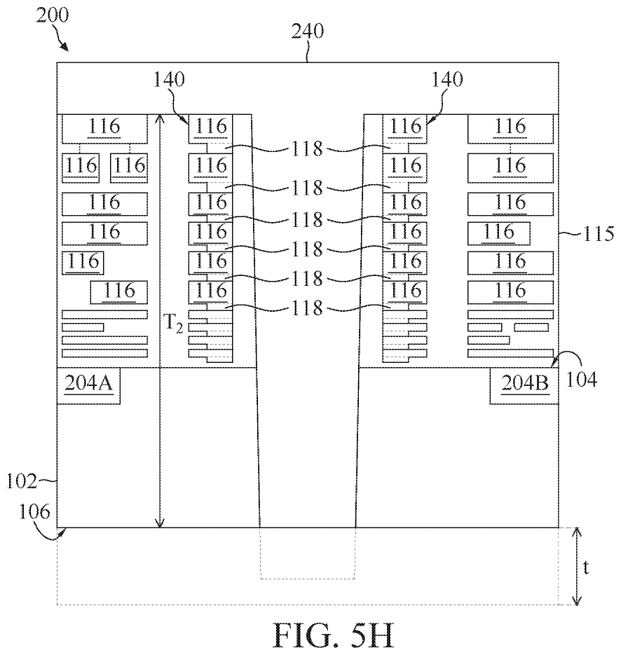

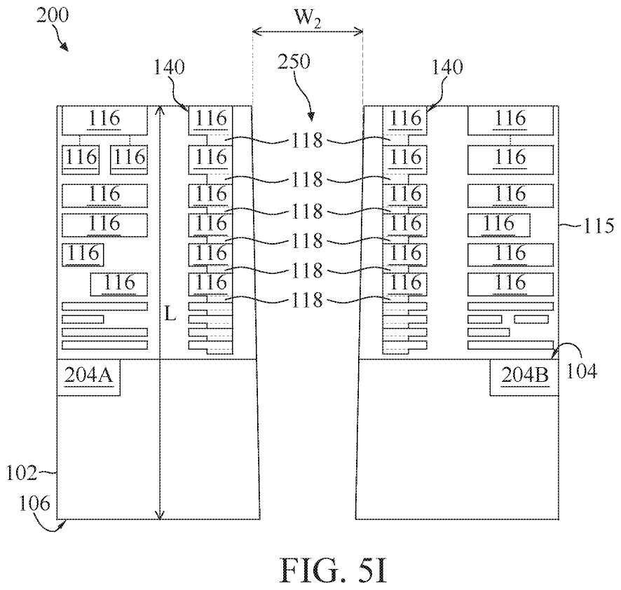

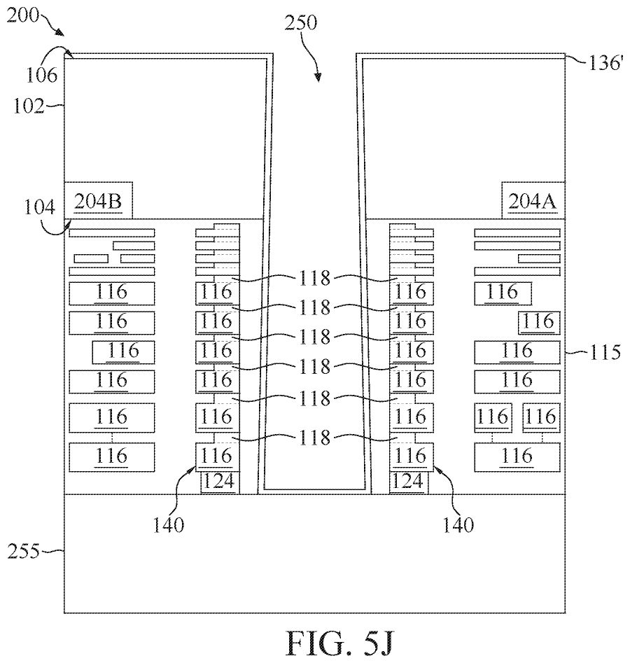

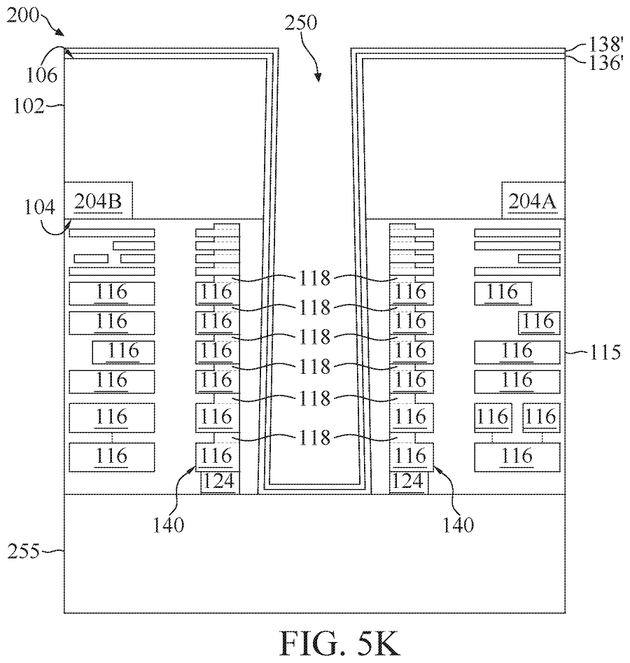

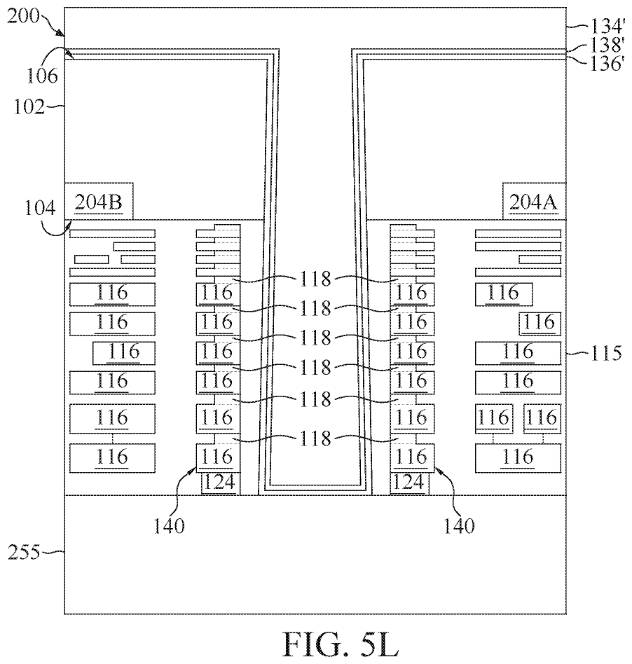

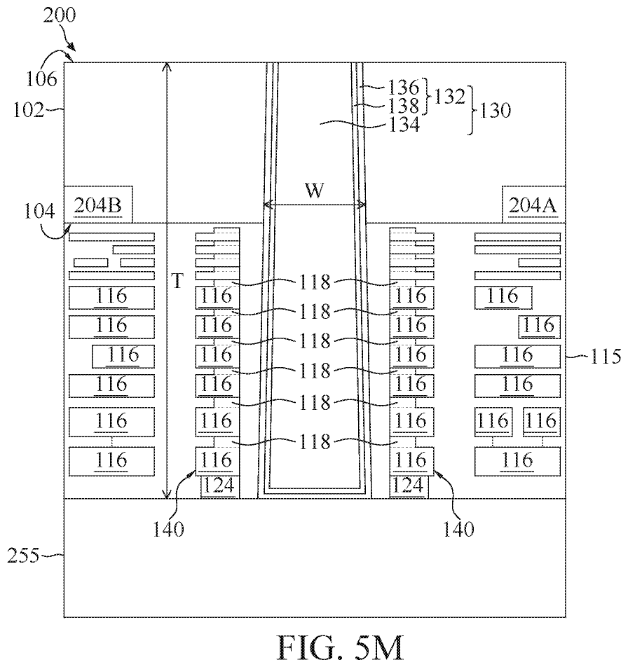

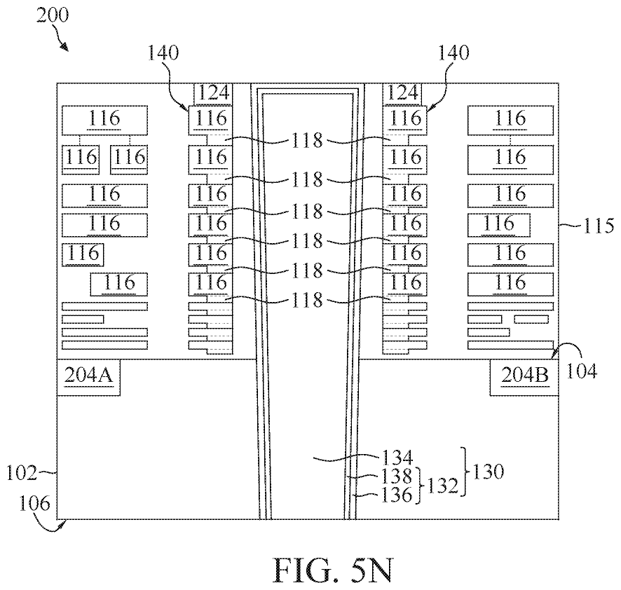

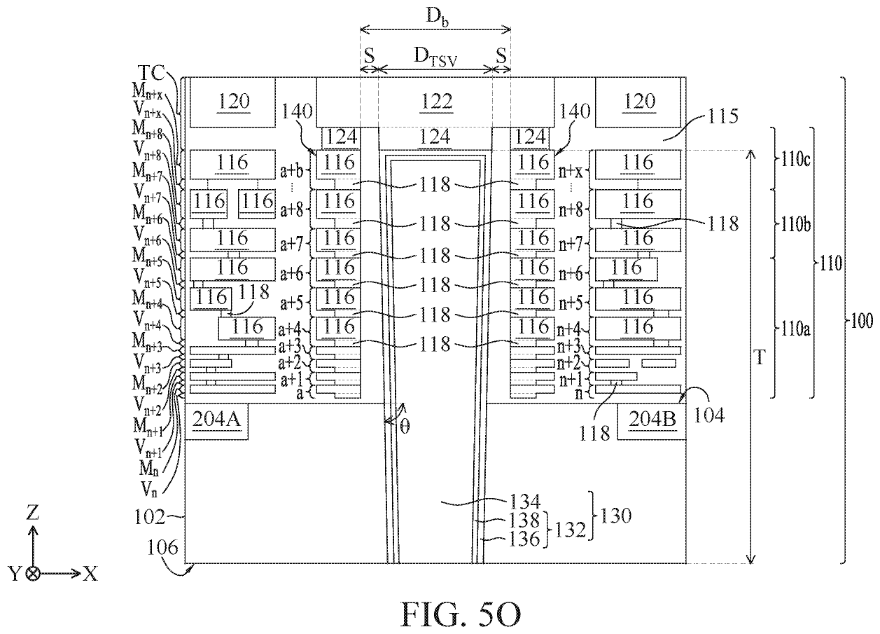

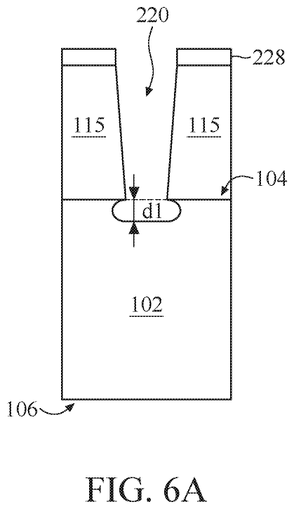

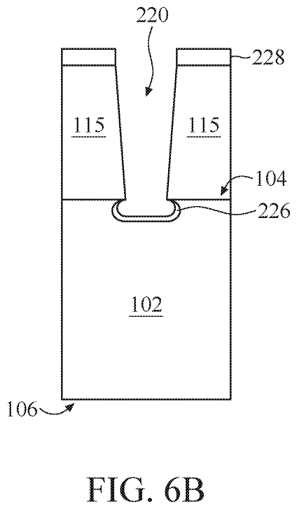

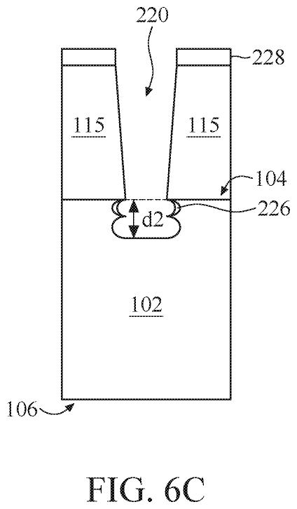

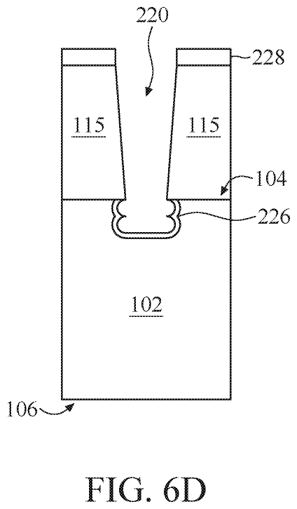

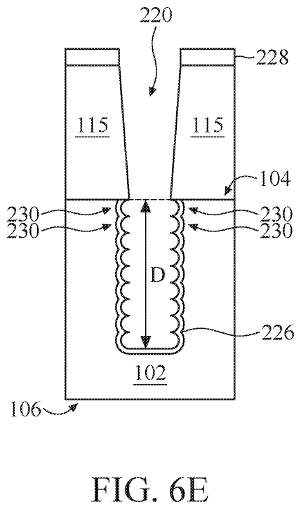

FIGS. 5A-50 are cross-sectional views of a workpiece 200, in portion or entirety, at various fabrication stages of forming a TSV according to various aspects of the present disclosure. FIGS. 6A-6E are cross-sectional views of a portion of workpiece 200, in portion or entirety, at various fabrication stages of forming a TSV trench, which can be implemented at the fabrication stage associated with FIG. 5E, according to various aspects of the present disclosure. For ease of description and understanding, the following discussion of FIGS. 5A-50 and FIGS. 6A-6E is directed to fabricating semiconductor structure 100 of FIG. 1 and FIG. 2, which includes TSV 130 and guard ring 140. However, the present disclosure contemplates embodiments where processing associated with FIGS. 5A-50 and/or FIGS. 6A-6E are implemented to fabricate workpieces having different configurations of TSV 130 and/or guard ring 140, such as those described herein. FIGS. 5A-50 and FIGS. 6A-6E have been simplified for the sake of clarity to better understand the inventive concepts of the present disclosure. Additional features can be added in workpiece 200, and some of the features described below can be replaced, modified, or eliminated in other embodiments of workpiece 200.

Referring to FIGS. 5A-5C, after workpiece 200 has undergone FEOL processing and MEOL processing, workpiece 200 undergoes BEOL processing to form MLI feature 110 over a device region 202A and/or a device region 202B of device substrate 102. MLI feature 110 may be physically and/or electrically connected to a device, such as a device 204A (e.g., a transistor) formed in device region 202A and/or a device 204B (e.g., another transistor) formed in device region 202B. Guard ring 140 can be formed over an intermediate region 202C of device substrate 102 while forming MLI feature 110. Guard ring 140 may be physically and/or electrically connected to a doped region, such as an n-well or a p-well, formed in device substrate 102. Guard ring 140 is an electrically conductive ring (e.g., a metal ring) having an inner dimension D_{b} that defines a dielectric region 210 of insulation layer 115. As described further below, TSV 130 is formed to extend through dielectric region 210.

In FIG. 5A, 1st level interconnect layer of MLI feature 110 (i.e., V₁ layer and M₁ layer) and 1^{st} interconnect structure of guard ring 140 (e.g., a interconnect structure) is formed over device substrate 102. For example, a patterned via layer (i.e., vias 118) is formed over device substrate 102 and a patterned metal layer (i.e., metal lines 116) is formed over the patterned via layer. In some embodiments, the patterned via layer is formed by depositing a portion of insulation layer 115 over an MEOL layer, performing a lithography and etching process to form openings in the portion of the insulation layer 115 that expose underlying conductive features (e.g., contacts and/or vias of the MEOL layer or device features, such as gates and/or source/drains), filling the openings with an electrically conductive material, and performing a planarization process that removes excess electrically conductive material, where the remaining electrically conductive material that fills the openings provides vias 118. Vias 118 and the portion of insulation layer 115 may form a substantially planar, common surface after the planarization process. In some embodiments, the patterned metal layer is formed by depositing a portion of insulation layer 115 over the patterned via layer, performing a lithography and etching process to form openings in the portion of the insulation layer 115 that expose underlying conductive features (e.g., vias 118 of 1st level interconnect layer and vias of 1^{st} interconnect structure), filling the openings with an electrically conductive material, and performing a planarization process that removes excess electrically conductive material, where the remaining electrically conductive material that fills the openings provides metal lines 116. Metal lines 116 and the portion of insulation layer 115 may form a substantially planar, common surface after the planarization process. In some embodiments, vias 118 and metal lines 116 are formed by respective single damascene processes (i.e., vias 118 are formed separately from their corresponding overlying and/or underlying metal lines 116). In some embodiments, vias 118 and metal lines 116 are formed by a dual damascene process, as described further below.

In some embodiments, depositing the portion of insulation layer 115 includes depositing an ILD layer. In some embodiments, depositing the portion of insulation layer 115 includes depositing a CESL before depositing the ILD layer, such that the ILD layer is deposited over the CESL. The portion of insulation layer 115 (e.g., the ILD layer and/or the CESL) are formed by chemical vapor deposition (CVD), plasma enhanced CVD (PECVD), high density plasma CVD (HDPCVD), flowable CVD (FCVD), physical vapor deposition (PVD), atomic layer deposition (ALD), metalorganic chemical vapor deposition (MOCVD), remote plasma CVD (RPCVD), low-pressure CVD (LPCVD), atomic layer CVD (ALCVD), atmospheric pressure CVD (APCVD), other suitable deposition method, or a combination thereof. A planarization process can be performed after depositing the portion of insulation layer 115.

In some embodiments, 1st level interconnect layer of MLI feature 110 and/or 1^{st} interconnect structure of guard ring 140 are formed by a dual damascene process, which can involve depositing conductive material for via/metal line pairs at the same time. In such embodiments, vias 118 and metal lines 116 may share a barrier layer and a conductive plug, instead of each having a respective and distinct barrier layer and conductive plug (e.g., where a barrier layer of a respective metal line 116 separates a conductive plug of the respective metal line 116 from a conductive plug of its corresponding, respective via 118). In some embodiments, the dual damascene process includes performing a patterning process to form interconnect openings that extend through insulation layer 115 to expose underlying conductive features. The patterning process can include a first lithography step and a first etch step to form trench openings of the interconnect openings (which correspond with and define metal lines 116) in insulation layer 115 and a second lithography step and a second etch step to form via openings of the interconnect openings (which correspond with and define vias 118) in insulation layer 115. The first lithography/first etch step and the second lithography/second etch step can be performed in any order (e.g., trench first via last or via first trench last). The first etch step and the second etch step are each configured to selectively remove insulation layer 115 with respect to a patterned mask layer. The first etch step and the second etch step may be a dry etching process, a wet etching process, other suitable etching process, or a combination thereof.

After performing the patterning process, the dual damascene process can include performing a first deposition process to form a barrier material over insulation layer 115 that partially fills the interconnect openings and performing a second deposition process to form a bulk conductive material over the barrier material, where the bulk conductive material fills remainders of the interconnect openings. In such embodiments, the barrier material and the bulk conductive material are disposed in the interconnect openings and over a top surface of insulation layer 115. The first deposition process and the second deposition process can include CVD, PVD, ALD, HDPCVD, MOCVD, RPCVD, PECVD, LPCVD, ALCVD, APCVD, PEALD, electroplating, electroless plating, other suitable deposition method, or a combination thereof. A CMP process and/or other planarization process is then performed to remove excess bulk conductive material and barrier material from over a top surface of the portion of insulation layer 115, resulting in the patterned via layer (e.g., vias 118) and the patterned metal layer (e.g., metal lines 116) of 1st level interconnect layer of MLI feature 110 and corresponding 1^{st} interconnect structure of guard ring 140. The CMP process planarizes top surfaces of insulation layer 115 and vias 118 and/or metal lines 116. The barrier material and the bulk conductive material may fill the trench openings and the via openings of the interconnect openings without interruption, such that barrier layers and conductive plugs of metal lines 116 and vias 118 may each extend continuously from metal lines 116 to respective vias 118 without interruption.

In FIG. 5B, 2^{nd} level interconnect layer through 6th level interconnect layer of MLI feature 110 (i.e., (n+1) level interconnect layer through (n+5) interconnect layer) are formed over 1^{st} level interconnect layer. 2^{nd} interconnect structure through 6^{th} interconnect structure of guard ring 140 (i.e., (a+1) interconnect structure through (a+5) interconnect structure) are formed while forming 2^{nd} level interconnect layer through 6^{th} level interconnect layer, respectively. Each of 2^{nd} level interconnect layer through 6^{th} level interconnect layer of MLI feature 110, and 2^{nd} interconnect structure through 6^{th} interconnect structure of guard ring 140 corresponding therewith, may be formed as described above with reference to fabrication of 1^{st} level interconnect layer of MLI feature 110 and 1^{st} interconnect structure of guard ring 140.

In FIG. 5C, 7^{th} level interconnect layer through 10^{th} level interconnect layer of MLI feature 110 (i.e., (n+6) level interconnect layer through (n+x) level interconnect layer) are formed over 6^{th} level interconnect layer. 7^{th} interconnect structure through 10^{th} interconnect structure of guard ring 140 (i.e., (a+6) interconnect structure through (a+b) interconnect structure) are formed while forming 7^{th} level interconnect layer through 10^{th} level interconnect layer, respectively. Each of 7^{th} level interconnect layer through 10^{th} level interconnect layer of MLI feature 110, and 7^{th} interconnect structure through 10^{th} interconnect structure of guard ring 140 corresponding therewith, may be formed as described above with reference to fabrication of 1^{st} level interconnect layer of MLI feature 110 and 1^{st} interconnect structure of guard ring 140.

In FIGS. 5A-5C, for a given level interconnect layer, metal lines 116 and vias 118 of an interconnect structure of guard ring 140 at the given level interconnect layer can be formed simultaneously with (e.g., by the same patterning processes and deposition processes), partially simultaneously with (e.g., by the same patterning processes but different deposition processes, or vice versa), or separately from (e.g., by different patterning processes and different deposition processes) metal lines 116 and vias 118, respectively, of the given level interconnect layer.

In FIG. 5D, a trench 220 is formed in dielectric region 220 of insulation layer 115. Trench 220 extends through insulation layer 115 to expose side 104 of device substrate 102. Trench 220 has a width W₁ along the x-direction that is less than inner dimension D_{B} of guard ring 140. Width W₁ may be substantially the same as a desired width of TSV 130. In some embodiments, width W₁ is about dimension D_{TSV}. In some embodiments, forming trench 220 includes forming a patterned mask layer 222 having an opening 224 therein that exposes dielectric region 210 of insulation layer 115 and etching insulation layer 115 using the patterned mask layer as an etch mask. The etching is a dry etching process, a wet etching process, other etching process, or a combination thereof. A width of opening 224 can be configured to provide a desired spacing between guard ring 140 and subsequently formed TSV 130. For example, opening 224 is provided with a width that is about equal to a desired width and/or a desired diameter of TSV 130. In some embodiments, a ratio of dimension D_{B} to a width of opening 224 is substantially the same as a ratio of dimension D_{B} to dimension D_{TSV}. Controlling spacing between guard ring 140 and trench 220 can reduce defects that may arise from extending trench 220 into device substrate 102 (i.e., defects caused by a TSV drilling process).

Patterned mask layer 222 can be formed using a lithography process, which can include resist coating (e.g., spin-on coating), pre-exposure baking (e.g., soft baking), mask aligning, exposure, post-exposure baking, developing the resist, rinsing, drying (e.g., hard baking), other suitable process, or a combination thereof. In some embodiments, patterned mask layer 222 is a hard mask layer, such as a silicon nitride layer, a silicon oxynitride layer, or other suitable layer including a suitable hard mask material. In some embodiments, patterned mask layer 222 is a patterned resist layer. In some embodiments, patterned mask layer 222 has a multilayer structure, such as a resist layer and a hard mask layer. For example, a hard mask layer is deposited over insulation layer 115, a lithography process is performed to form a patterned resist layer over the hard mask layer (e.g., spin-on coating, exposing, developing, etc.), and an etching process removes exposed portions of the hard mask layer to form a patterned hard mask layer, where the etching process can use the patterned resist layer as an etch mask.

In FIG. 5E, trench 220 is extended into device substrate 102 to a depth d by a suitable process, such as an etching process. Depth d is less than a thickness of device substrate 102 (e.g., a thickness of device substrate 102 along the z-direction (i.e., from side 104 to side 106)). In some embodiments, depth d is about 3 μm to about 10 μm. In some embodiments, trench 220 extends beyond active devices, passive devices, and/or device features formed within and/or on device substrate 102 at side 104 (e.g., trench 220 extends further into device substrate 102 than isolation structures formed therein). In some embodiments, trench 220 extends through device substrate 102, such as from side 104 to side 106 (i.e., depth d is equal to the thickness of device substrate 102). The etching process is a dry etching process, a wet etching process, other etching process, or a combination thereof. In some embodiments, the etching process is a dry etching process, such as an isotropic dry etch (i.e., an etching process that will remove material in more than one direction, such as vertically along the z-direction and laterally along the x-direction). In some embodiments, the etching process is a plasma etching process. In some embodiments, trench 220 is extended into device substrate 102 by a laser drilling process. In some embodiments, the etching process uses patterned mask layer 222 as an etch mask, and patterned mask layer 222 is removed after extending trench 220 into device substrate 202 by a suitable process, such as a stripping process, an ashing process, an etching process, or a combination thereof. In some embodiments, patterned mask layer 222 is removed before extending trench 220 into device substrate 202 by a suitable process.

In some embodiments, a Bosch process, such as depicted in FIGS. 6A-6E, is implemented to extend trench 220 into device substrate 102. A Bosch process generally refers to a high-aspect ratio plasma etching process that involves alternating etch phases and deposition phases, where a cycle includes an etch phase and a deposition phase and the cycle is repeated until trench 220 has desired depth d. For example, the Bosch process can include introducing a first gas (e.g., a fluorine-containing gas, such as SF₆) into a process chamber to etch device substrate 102 (e.g., silicon) and extend trench 220 to a depth d1 in device substrate 102 that is less than depth d (FIG. 6A, an etch phase); stopping and/or reducing the first gas and introducing and/or increasing a second gas (e.g., a fluorine-containing gas, such as C₄F₈) into the process chamber that forms a protective layer 226 over surfaces of device substrate 102 that form trench 220 (FIG. 6B, a deposition phase); stopping and/or reducing the second gas and introducing and/or increasing the first gas into the process chamber to further etch device substrate 102 and extend trench 220 to a depth d2 in device substrate 102 that is less than depth d (FIG. 6C, an etch phase); stopping and/or reducing the first gas and introducing and/or increasing the second gas into the process chamber that forms protective layer 226 (also referred to as a polymer layer or a passivation layer) over exposed surfaces of device substrate 102 that form trench 220 (FIG. 6D, a deposition phase); and repeating cycles of the Bosch process (i.e., etch phase plus polymer deposition phase) until trench 220 extends to depth d in device substrate 102 (FIG. 6E). Each etch phase may remove portions of protective layer 226 that cover surfaces of device substrate 102 that form a bottom of trench 220, but not (or minimal) portions of protective layer 226 that cover surfaces of device substrate 102 that form sidewalls of trench 220. Protective layer 226 can include fluorine and carbon (i.e., a fluorocarbon-based layer). The Bosch process can use a patterned mask layer 228 as an etch mask having an opening therein that overlaps trench 220 in insulation layer 115. In some embodiments, patterned mask layer 228 was formed and used as an etch mask when forming trench 220 in insulation layer 115 in FIG. 5D. In other words, patterned mask layer 228 may be patterned mask layer 222 in FIG. 5D.

In FIG. 6E, because the Bosch process laterally etches (as well as vertically etches) device substrate 102 during the etch phases, trench 220 may have scalloped sidewalls, wavy sidewalls, rough sidewalls, or a combination thereof, which are formed by curvilinear segments/surfaces 230 of device substrate 102. Rough sidewalls can negatively impact subsequently formed TSV 130. For example, TSV 130 may delaminate from scalloped sidewalls of device substrate 102. Accordingly, referring to FIG. 5F, a smoothing process can be performed on sidewalls of trench 220. Parameters of the smoothing process are tuned to remove scalloped sidewalls, wavy sidewalls, rough sidewalls, or a combination thereof that form trench 220. For example, trench 220 has substantially linear sidewalls and/or substantially flat sidewalls 232 after the smoothing process. In some embodiments, the smoothing process is an etching process that selectively removes a semiconductor material (e.g., silicon portions of device substrate 102) with minimal (to no) removal of a dielectric material (e.g., insulation layer 115). The etching process is a dry etching process, a wet etching process, other etching process, or a combination thereof. In some embodiments, the smoothing process also removes protective layer 226 from trench 220. In some embodiments, the smoothing process may not be performed and protective layer 226 may be removed by a suitable process, such as an etching process, before proceeding with forming TSV 130 in trench 220. In some embodiments, sidewalls of trench 220 are smoothed and protective layer 226 are removed by separate processes. Patterned mask layer 222 can be removed before or after the smoothing process.

In FIG. 5F, trench 220 has a depth D and a width W₁. In some embodiments, depth D is about 5 μm to about 100 μm. In some embodiments, width W₁ (a diameter of trench 220, in some embodiments) is about 1 μm to about 18 μm. Trench 220 may have a high aspect ratio. For example, an aspect ratio (i.e., a ratio of depth D to width W₁) is greater than about 10. In some embodiments, the aspect ratio is about 5 to about 20. Typically, fabrication proceeds with forming TSV 130 in trench 220 by depositing an electrically conductive material (e.g., copper) over insulation layer 115 (and thus over side 104 of device substrate 102) that fills trench 220, performing a planarization process that removes the electrically conductive material from over a top surface of insulation layer 115, and thinning device substrate 102 from side 106 to expose the electrically conductive material. Because trench 220 has a high aspect ratio and/or a large depth, the electrically conductive material may fill or close off portions of trench 220 before completely filling trench 220 (i.e., pinch off occurs during gap fill). This results in voids (seams) and/or keyholes in the electrically conductive material. The voids and/or the keyholes can degrade electrical performance of TSV 130 and/or semiconductor structure 100, for example, by increasing resistance and/or inhibiting electrical communication between device components of stacked ICs. Further, since a portion of the electrically conductive material is often removed when thinning device substrate 102, the typical TSV fabrication technique uses more electrically conductive material than necessary, thereby increasing fabrication costs. As described herein, the disclosed TSV fabrication technique addresses these issues by reducing an aspect ratio and/or a depth of a TSV opening (trench 220) before forming TSV 130 therein and thinning device substrate 102 before forming TSV 130, which can minimize and/or prevent pinch off (and thus inhibit void formation in TSV 130) and eliminate conductive material waste.

In FIG. 5G, fabrication proceeds with a TSV dielectric gap fill step, which includes forming a dielectric layer 240 over insulation layer 115 that fills trench 220. Dielectric layer 240 is thus formed over side 104 (e.g., frontside) of device substrate 102. A portion of dielectric layer 240 fills trench 220 and extends through insulation layer 115 and into device substrate 102. The portion of dielectric layer 240 has a thickness T1, which is substantially the same as depth D of trench 220, and width W1. A composition of dielectric layer 240 is different than a composition of insulation layer 115 and a composition of device substrate 102 to achieve etch selectivity during subsequent processing. In other words, dielectric layer 240, insulation layer 115, and device substrate 102 include materials having distinct etching sensitivities to a given etchant, such that dielectric layer 240 can be selectively etched/removed with minimal (to no) etching/removal of insulation layer 115 and/or device substrate 102. In some embodiments, dielectric layer 240 includes an oxide material, such as a silicon oxide material. In some embodiments, dielectric layer 240 includes an oxide material that is the same as an oxide material of an isolation structure (e.g., an STI) in device substrate 102. In some embodiments, dielectric layer 240 includes a flowable oxide material, such as an oxide material formed by FCVD. In some embodiments, dielectric layer 240 includes a gap fill oxide material, such as an oxide material formed by ALD. Dielectric layer 240 can be formed by CVD, PECVD, HDPCVD, FCVD, MOCVD, RPCVD, LPCVD, ALCVD, APCVD, other deposition process, or a combination thereof. In some embodiments, a planarization process (e.g., CMP) is performed to remove dielectric layer 240 from over a top surface of insulation layer 115 and/or a top surface of a top patterned metal layer, such as that formed by top metal lines 116. In such embodiments, the planarization process can stop upon reaching insulation layer 115 and/or the top patterned metal layer, and the planarization process can planarize the top surface of insulation layer 115, the top surface of the top patterned metal layer, and a top surface of a remainder of dielectric layer 240. Further, in such embodiments, a remainder of dielectric layer 240, which fills trench 220, can be referred to as a dielectric plug.

In FIG. 5H, a thinning process is performed on device substrate 102 to expose dielectric layer 240, such that dielectric layer 240 extends through device substrate 102. For example, after the thinning process, dielectric layer 240 extends from side 104 (e.g., frontside) to side 106 (e.g., backside) of device substrate 102. The thinning process is a grinding process, a planarization process (e.g., CMP), an etching process, other suitable process, or a combination thereof. The thinning process is applied to side 106 of device substrate 102. During the thinning process, dielectric layer 240 maintains a shape and/or a profile of trench 220. In some embodiments, workpiece 200 is attached to a carrier wafer (substrate) before performing the thinning process. For example, dielectric layer 240 can be attached/bonded to a carrier wafer before the thinning process. In another example, such as where a planarization process is performed to expose insulation layer 115 before the thinning process, insulation layer 115, the top patterned metal layer (e.g., top metal lines 116), dielectric layer 240, or a combination thereof can be attached/bonded to a carrier wafer before the thinning process.

The thinning process reduces a thickness of device substrate 102 along the z-direction. For example, the thinning process removes a thickness t of device substrate 102. In some embodiments, thickness t is about 1 μm to about 95 μm. In some embodiments, thickness t is greater than about 10 μm. In the depicted embodiment, the thinning process removes a portion of dielectric layer 240 that fills trench 220, such that the portion of dielectric layer 240 filling trench 220 has a thickness T2 after the thinning process. Thickness T2 is less than thickness T1, and thickness T2 is substantially the same as a desired thickness (e.g., thickness T) of a subsequently formed TSV (e.g., TSV 130). Because trench 220 is filled with dielectric layer 240, instead of a TSV, a thickness of device substrate 102 removed during the thinning process is greater than that removed which can be removed when the thinning process is performed after forming the TSV in trench 220. An aspect ratio of trench 220 can thus be reduced before forming the TSV therein, which can improve gap fill. In some embodiments, the thinning process stops upon reaching dielectric layer 240, such that the portion of dielectric layer 240 filling trench 220 has thickness T1 after the thinning process. In such embodiments, thickness T1 is substantially the same as a desired thickness of a subsequently formed TSV.

In FIG. 5I, dielectric layer 240 is removed from workpiece 200 to provide a TSV opening 250 (which corresponds with trench 220 having a smaller aspect ratio). TSV opening 250 has a length L and a width W₂. Length L is less than depth D of trench 220 before forming dielectric layer 240 therein (and thus is less than thickness T1 of dielectric layer 240), and length L is substantially the same as a desired thickness of TSV 130 (e.g., length L≈thickness T). Accordingly, an aspect ratio of TSV opening 250 (i.e., a ratio of length L to width W₂) is less than the aspect ratio of trench 220 (i.e., a ratio of depth D to width W₁) before forming dielectric layer 240 therein and performing the thinning process. For example, an aspect ratio of TSV opening 250 is less than about 10, such as about 1.5 to about 10. In some embodiments, the aspect ratio of TSV opening 250 is about 1.5 to about 20. In some embodiments, length L is about 3 μm to about 98 μm. Width W₂ is substantially the same as a desired thickness of TSV 130 (e.g., width W₂≈width W), and width W₂ is greater than or equal to width W₁. In some embodiments, width W₂ is about 1 μm to about 18 μm.

The etching process is configured to selectively remove dielectric layer 240 with respect to insulation layer 115, metal lines 116, device substrate 102, or a combination thereof. For example, the etching process removes dielectric layer 240 but does not remove, or negligibly removes, insulation layer 115, metal lines 116, device substrate 102, or a combination thereof. For example, an etchant is selected for the etch process that etches dielectric layer 240 (e.g., a dielectric material having a first composition) at a higher rate than the materials of insulation layer 115 (e.g., a dielectric material having a second composition that is different than the first composition), metal lines 116 (e.g., metal materials), device substrate 102 (e.g., semiconductor materials), or a combination thereof (i.e., the etchant has a high etch selectivity with respect to dielectric layer 240, such as the dielectric material having the first composition). The etching process is a dry etching process, a wet etching process, other etching process, or a combination thereof. In some embodiments, the etching process is a two-step process, such as a first etching process that uses a first etchant to selectively remove dielectric layer 240 relative to insulation layer 115 and a second etching that uses a second etchant to selectively remove dielectric layer 240 relative to device substrate 102. In some embodiments, a single etchant selectively removes dielectric layer 240 relative to insulation layer 115 and device substrate 102. Various parameters (e.g., etchant type, etching time, etching pressure, etching temperature, etc.) can be tuned to achieve selective etching of dielectric layer 240. In some embodiments, a cleaning process and/or a surface treatment process (collectively referred to as a cleaning process) is performed after the etching process to remove defects from surfaces of insulation layer 115 and/or device substrate 102 that define/form TSV opening 250, such as any native oxide, contaminates, remnants of dielectric layer 240, or a combination thereof. In some embodiments, the etching process uses a patterned mask layer as an etch mask, wherein the patterned mask layer covers the top surface of insulation layer 115 and the top surface of the top patterned metal layer, the patterned mask layer exposes dielectric layer 240 (e.g., the dielectric plug), and the patterned mask layer is removed during and/or after removal of dielectric layer 240.

In FIGS. 5J-5N, fabrication proceeds with forming TSV 130 in TSV opening 250. In FIG. 5J, a dielectric layer 136′ is formed that partially fills TSV opening 250. In the depicted embodiment, workpiece 200 is flipped over before forming TSV 130, such that device substrate 102 forms a top of workpiece 200 instead of insulation layer 115. Because workpiece 200 is flipped over, dielectric layer 136′ is formed over and covers side 106 (e.g., backside) of device substrate 102, sidewalls of TSV opening 250 (here, formed by insulation layer 115), and a top/bottom of TSV opening 250 (here, formed in insulation layer 115 and extending between the sidewalls of the TSV opening 250). Dielectric layer 136′ has vertically oriented segments (i.e., portions that line the sidewalls of TSV opening 250) and a horizontally oriented segment that extends between the vertically oriented segments (i.e., a portion that lines the top/bottom of TSV opening 250). The vertically oriented segments are disposed in insulation layer 115 and device substrate 102, while the horizontally oriented segment is disposed in insulation layer 115. In some embodiments, workpiece 200 is attached to a carrier wafer (substrate) 255 before forming TSV 130. For example, insulation layer 115 and/or the top patterned metal layer (e.g., top metal lines 116) can be attached/bonded to carrier wafer 255 before forming dielectric layer 136′, and then workpiece 200 can be flipped over. In such embodiments, carrier wafer 255 forms the top/bottom of TSV opening 250 and dielectric layer 136′ covers carrier wafer 255.

Dielectric layer 136′ includes a dielectric material, which can include silicon, oxygen, carbon, nitrogen, other suitable dielectric constituent, or a combination thereof (e.g., silicon oxide, silicon nitride, silicon oxynitride, etc.). For example, dielectric layer 136′ includes oxygen and is referred to as an oxide layer. In some embodiments, dielectric layer 136′ further includes silicon, and dielectric layer 136′ is a silicon oxide layer. In some embodiments, dielectric layer 136′ is a TEOS oxide layer. In some embodiments, dielectric layer 136′ is a silicon nitride layer. Dielectric layer 136′ is formed by CVD (e.g., PECVD and/or LPCVD), thermal oxidation, chemical oxidation, other suitable deposition process, or a combination thereof. In the depicted embodiment, dielectric layer 136′ is conformally deposited over workpiece 200, such that dielectric layer 136′ has a substantially uniform thickness.

In FIG. 5K, a barrier/seed layer 138′ is formed over dielectric layer 136′ that partially fills TSV opening 250. Because workpiece 200 is flipped over, barrier/seed layer 138′ is formed over side 106 (e.g., backside) of device substrate 102, and barrier/seed layer 138′ is disposed over side 106 of device substrate 102, the sidewalls of TSV opening 250, and the top/bottom of TSV opening 250. Barrier/seed layer 138′ has vertically oriented segments (i.e., portions that line the sidewalls of TSV opening 250) and a horizontally oriented segment that extends between the vertically oriented segments (i.e., a portion that lines the top/bottom of TSV opening 250). The vertically oriented segments are disposed in insulation layer 115 and device substrate 102, while the horizontally oriented segment is disposed in insulation layer 115. Barrier/seed layer 138′ is formed by PVD, CVD, ALD, other suitable deposition process, or a combination thereof. In the depicted embodiment, barrier/seed layer 138′ is conformally deposited over workpiece 200, such that barrier/seed layer 138′ has a substantially uniform thickness.

Barrier/seed layer 138′ includes a material that can prevent diffusion of metal from a subsequently formed bulk layer into insulation layer 115, facilitate growth and/or deposition of the subsequently formed bulk layer, facilitate adhesion of the subsequently formed bulk layer and a dielectric material (e.g., dielectric layer 136′ and/or insulation layer 115), or a combination thereof. For example, barrier/seed layer 138′ includes titanium, titanium alloy (e.g., TiN, TiSiN, TiC, or a combination thereof), tantalum, tantalum alloy (e.g., TaN and/or TaC), tungsten, tungsten alloy (e.g., WN), aluminum, aluminum alloy (e.g., AlON and/or Al₂O₃), silicon (e.g., SiO₂), other suitable barrier/seed material, or a combination thereof. In some embodiments, barrier/seed layer 138′ has a multilayer structure, such as a barrier layer over dielectric layer 136′ (e.g., including a material that can inhibit diffusion of metal) and a seed layer (e.g., including a material that can facilitate deposition and/or adhesion of the subsequently formed bulk layer) over the barrier layer. For example, barrier/seed layer 138′ can include a metal nitride barrier layer and a copper seed layer. In some embodiments, the barrier layer and/or the seed layer have a multilayer structure. For example, the barrier layer can include a metal nitride layer (e.g., TaN layer or TiN layer) and a metal layer (e.g., Ta layer or Ti layer).

In FIG. 5L, a bulk layer 134′ is formed over barrier/seed layer 138′ that fills a remainder of TSV opening 250. Because workpiece 200 is flipped over, bulk layer 134′ is formed over side 106 (e.g., backside) of device substrate 102. Further, because an aspect ratio of TSV opening 250 is less than an aspect ratio of trench 220, bulk layer 134′ fills TSV opening 250 with minimal to no voids and/or keyholes formed therein. Bulk layer 134′ includes an electrically conductive material, such as aluminum, copper, titanium, tantalum, tungsten, ruthenium, cobalt, iridium, palladium, platinum, nickel, tin, gold, silver, other suitable metals, alloys thereof, silicides thereof, or a combination thereof. In some embodiments, bulk layer 134′ includes copper. In some embodiments, bulk layer 134′ includes tungsten. In some embodiments, bulk layer 134′ includes polysilicon. In some embodiments, bulk layer 134′ has a multilayer structure. Bulk layer 134′ is formed by electrochemical plating (ECP), electroplating, electroless plating. PVD, CVD, other suitable deposition process, or a combination thereof. In the depicted embodiment, bulk layer 134′ is blanket deposited over workpiece 200.

In FIG. 5M, a planarization process (e.g., CMP) is performed on workpiece 200. The planarization process removes TSV layers from over side 106 of device substrate 102, such as bulk layer 134′, barrier/seed layer 138′, and dielectric layer 136′. Device substrate 102 can function as a planarization stop layer, and the planarization process can be performed until reaching and exposing device substrate 102. A remainder of the TSV layers form TSV 130 having thickness T and width W. For example, a remainder of dielectric layer 136′ forms dielectric liner 136, a remainder of barrier/seed layer 138′ forms barrier/seed liner 138, and a remainder of bulk layer 134′ forms bulk layer 134 (also referred to as a conductive plug or a TSV plug). Dielectric liner 136 and barrier/seed liner 138 combine to form barrier layer 132 of TSV 130, which wraps bulk layer 134 of TSV 130. Because device substrate 210 is thinned before forming TSV 130, a portion of TSV 130 is not removed when fabricated as described with reference to FIGS. 5A-5M, thereby reducing conductive material waste and/or reducing fabrication costs. The planarization process can planarize side 106 of device substrate 102 (i.e., a back/bottom surface thereof) and a surface of TSV 130 (i.e., a back/bottom surface thereof). In some embodiments, side 106 of device substrate 102 and the surface of TSV 130 (i.e., a back/bottom surface thereof) are substantially planar after the planarization process.

In FIG. 5N, workpiece 200 is flipped back over, such that insulation layer 115, instead of device substrate 102, forms a top of workpiece 200. Workpiece 200 is thus re-oriented so that insulation layer 115 forms a top/front of workpiece 200 and device substrate 102 (e.g., side 106 thereof) forms a bottom/back of workpiece 200. Since TSV 130 extends through insulation layer 115 and device substrate 102, a top/frontside of TSV 130 also forms a top/front of workpiece 200, and a bottom/backside of TSV 130 also forms a bottom/back of workpiece 200. Further, because TSV 130 is formed as described with reference to FIGS. 5A-5M, the top/frontside of TSV 130 is formed by barrier layer 132 (e.g., dielectric liner 136) and the bottom/backside of TSV 130 is formed by bulk layer 134 and barrier layer 132. A horizontally oriented segment of barrier layer 132 is thus disposed in insulation layer 115 instead of device substrate 102. In some embodiments, dielectric liner 136 is omitted from TSV 130, barrier/seed layer 138 separates bulk layer 134 and insulation layer 115, barrier/seed layer 138 separates bulk layer 134 and device substrate 102, and the top/frontside of TSV 130 is formed by barrier/seed layer 138. In embodiments where insulation layer 115 is attached to carrier wafer 255 during TSV formation, carrier wafer 255 is removed before or after the planarization process.

In FIG. 5M, fabrication can proceed with forming TC layer over MLI feature 110, TSV 130, and guard ring 140. In some embodiments, forming TC layer includes depositing a passivation layer over workpiece 200 and patterning the passivation layer to have openings therein that expose metal lines 116 of (n+x) level interconnect layer of MLI feature 110, TSV 130, and metal lines 116 of (a+b) interconnect structure of guard ring 140 (i.e., topmost metal features). One of the openings in the patterned passivation layer may expose TSV 130, guard ring 140, and portion of insulation layer 115 between TSV 130 and guard ring 140. In some embodiments, forming TC layer can include depositing conductive material over workpiece 200 that fills the openings in the patterned passivation layer and performing a planarization process that removes excess conductive material from over a top surface of the passivation layer, thereby forming contacts 120, contact 122, and vias 124 in the passivation layer.

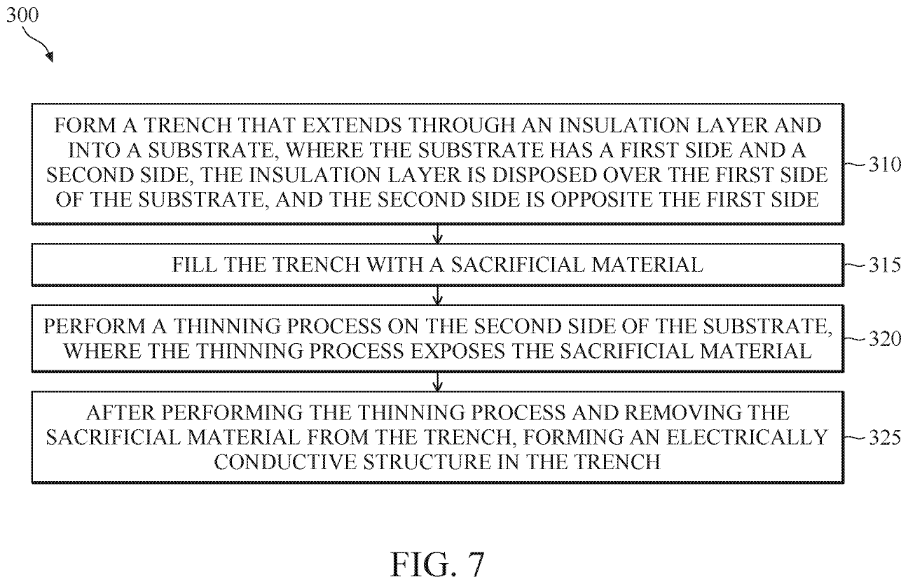

FIG. 7 is a flow chart of a method 300 for fabricating a through via, such as TSV 130, according to various aspects of the present disclosure. At block 310, method 300 includes forming a trench (e.g., trench 220) that extends through an insulation layer (e.g., insulation layer 115) and into a substrate (e.g., device substrate 102). The substrate has a first side (e.g., side 104 of device substrate 102) and a second side (e.g., side 106 of device substrate 102). The second side is opposite the first side, and the insulation layer is disposed over the first side of the substrate. At block 315, method 300 includes filling the trench with a sacrificial material (e.g., dielectric layer 240). At block 320, method 300 includes performing a thinning process on the second side of the substrate. The thinning process exposes the sacrificial material. In some embodiments, the thinning process removes a portion of the sacrificial material. At block 325, method 300 includes, after performing the thinning process and removing the sacrificial material from the trench, forming an electrically conductive structure in the trench. The electrically conductive structure extends through the substrate from the first side to the second side. The electrically conductive structure can include a liner that wraps an electrically conductive plug, and a portion of the liner that covers a top and/or a bottom of the electrically conductive plug is disposed in the insulation layer. In some embodiments, the trench has a first aspect ratio before filled with the sacrificial material and a second aspect ratio after the thinning process and removal of the sacrificial material. The second aspect ratio is less than the first aspect ratio. In some embodiments, the insulation layer and the substrate form a first semiconductor structure, which can be attached (bonded) to a second semiconductor structure. For example, a backside of the first semiconductor structure (e.g., formed by the second side of the substrate) is attached to the second semiconductor structure and the electrically conductive structure electrically and/or physically connects the first semiconductor structure and the second semiconductor structure. In another example, a frontside of the semiconductor structure (e.g., a portion thereof formed and/or disposed over the insulation layer) is attached to the second semiconductor structure and the electrically conductive structure electrically and/or physically connects the first semiconductor structure and the second semiconductor structure. In yet another example, a backside of the first semiconductor structure is attached to the second semiconductor structure and a frontside of the first semiconductor structure is attached to a third semiconductor structure. In such example, the electrically conductive structure electrically and/or physically connects the first semiconductor structure and the second semiconductor structure and/or the first semiconductor structure and the third semiconductor structure. FIG. 7 has been simplified for the sake of clarity to better understand the inventive concepts of the present disclosure. Additional steps can be provided before, during, and after method 300, and some of the steps described can be moved, replaced, or eliminated for additional embodiments of method 300.

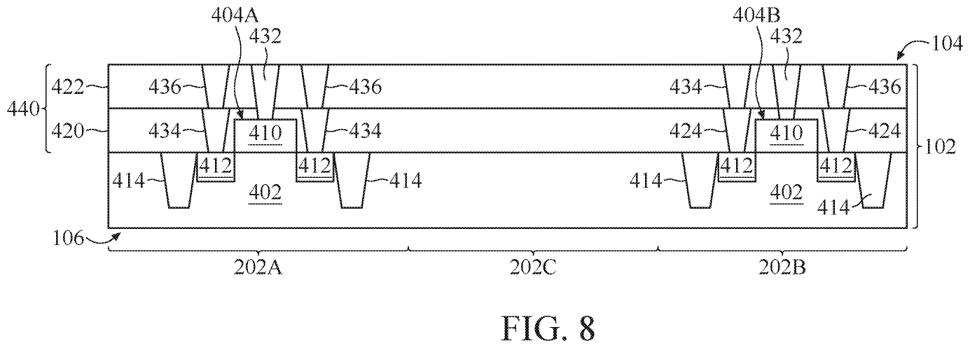

FIG. 8 is a fragmentary diagrammatic cross-sectional view of device substrate 102, in portion or entirety, according to various aspects of the present disclosure. In FIG. 8, device substrate 102 has device region 202A, device region 202B, and intermediate region 202C. Device substrate 102 is depicted with a semiconductor substrate 402 and various transistors, such as a transistor 404A in device region 202A and a transistor 404B in device region 202B. Transistor 404A and transistor 404B each include a respective gate structure 410 (which can include gate spacers disposed along a gate stack (e.g., a gate electrode disposed over a gate dielectric)) disposed between respective source/drains 412 (e.g., epitaxial source/drains), which are disposed on, in, and/or over semiconductor substrate 402, where a channel extends between respective source/drains 412 in semiconductor substrate 402. Device substrate 102 can further include isolation structures 414, such as shallow trench isolation features, that separate and/or electrically isolate transistors, such as transistor 404A and transistor 404B, and/or other devices of device substrate 102 from one another. Device substrate 102 further includes a dielectric layer 420 and a dielectric layer 422, which is similar to and can be fabricated similar to the dielectric layers described herein (i.e., dielectric layer 420 can include one or more ILD layers and/or one or more CESLs). Gate contacts 432 are disposed in dielectric layer 420 and dielectric layer 422, source/drain contacts 434 are disposed in dielectric layer 420, and vias 436 are disposed in dielectric layer 422. Gate contacts 432 electrically and physically connect gate structures 410 (in particular, gate electrodes) to MLI feature 110, and source/drain contacts 434 and/or vias 436 electrically and physically connect source/drains 412 to MLI feature 110. In some embodiments, dielectric layer 420, dielectric layer 422, gate contacts 432, source/drain contacts 434, and vias 436 form an MEOL layer 440. In some embodiments, gate contacts 432, source/drain contacts 434, vias 436, or a combination thereof are physically and/or electrically connected to n level interconnect layer of MLI feature 110. In some embodiments, gate contacts 432 and/or vias 436 may form a portion of Vₙ layer of n level interconnect layer, and gate contacts 432 and/or vias 436 are physically and/or electrically connected to Mₙ layer of n level interconnect layer. In some embodiments, dielectric layer 420 and/or dielectric layer 422 form a portion of insulation layer 115. In some embodiments, contacts are disposed in dielectric layer 420 over a doped region in semiconductor substrate 402 in interface region 202C, and vias are disposed in dielectric layer 422 over the contacts. Such contacts may be physically and/or electrically connected to the doped region, and such vias may be vias 118 of a interconnect structure of guard ring 140 and disposed in Vₙ layer of n level interconnect layer. In such embodiments, guard ring 140 can be physically and/or electrically connected to the doped region in semiconductor substrate 402. FIG. 8 has been simplified for the sake of clarity to better understand the inventive concepts of the present disclosure. Additional features can be added in device substrate 102, and some of the features described below can be replaced, modified, or eliminated in other embodiments of device substrate 102.

Through via structures and methods of fabrication thereof are disclosed herein. The present disclosure provides for many different embodiments. An exemplary method forming a through substrate via includes forming a trench that extends through an insulation layer and into a substrate. The substrate has a first side and a second side, and the second side is opposite the first side. The insulation layer is disposed over the first side of the substrate. The method further includes filling the trench with a dielectric material and performing a thinning process on the second side of the substrate. The thinning process exposes the dielectric material. After performing the thinning process and removing the dielectric material from the trench, the method further includes forming an electrically conductive structure in the trench. The electrically conductive structure extends through the substrate from the first side to the second side.

In some embodiments, the first side and the second side of the substrate are a frontside and a backside, respectively. In some embodiments, the dielectric material filling the trench has a first thickness and the thinning process removes a portion of the dielectric material, thereby providing the dielectric material filling the trench with a second thickness that is less than the first thickness. In some embodiments, the trench has a first aspect ratio before filled with the dielectric material, and after the thinning process and removing the dielectric material from the trench, the trench has a second aspect ratio less than the first aspect ratio, and the electrically conductive structure fills the trench having the second aspect ratio.

In some embodiments, forming the electrically conductive structure in the trench includes forming a barrier layer in the trench that forms a top and sidewalls of the electrically conductive structure and forming an electrically conductive layer over the barrier layer in the trench. A portion of the barrier layer that forms the top of the electrically conductive structure is disposed in the insulation layer. In some embodiments, forming the barrier layer includes depositing a dielectric liner over the second side of the substrate and depositing a metal-comprising liner over the dielectric liner. The dielectric liner and the metal-comprising liner partially fill the trench, and the electrically conductive layer is formed over the metal-comprising liner and fills a remainder of the trench. In some embodiments, a planarization process is performed to remove portions of the dielectric liner, the metal-comprising liner, the electrically conductive layer, or a combination thereof from the second side of the substrate. In some embodiments, the barrier layer includes a metal-comprising liner, but not a dielectric liner.

In some embodiments, removing the dielectric material includes performing an etching process that selectively removes the dielectric material relative to the insulation layer and the substrate. In some embodiments, the insulation layer and the substrate form a semiconductor structure, and the method further includes flipping the semiconductor structure, such that the forming the electrically conductive structure in the trench includes depositing electrically conductive material over the second side of the substrate. In some embodiments, the insulation layer and the substrate form a first semiconductor structure, and the method includes bonding the first semiconductor structure to a second semiconductor structure. The electrically conductive structure connects the first semiconductor structure and the second semiconductor structure.

In some embodiments, after the thinning process and removing of the dielectric material from the trench, the trench has a top critical dimension in the insulation layer, a middle critical dimension proximate an interface of the insulation layer and the first side of the substrate, and a bottom critical dimension in the substrate. In some embodiments, a ratio of the top critical dimension to the middle critical dimension to the bottom critical dimension is about 1:1:1 to about 4:2:1. In some embodiments, a ratio of the top critical dimension to the middle critical dimension to the bottom critical dimension is about 1:2:4 to about 1:1:1.

Another exemplary method includes receiving a workpiece having a device substrate and a multilayer interconnect (MLI) feature. The device substrate has a first thickness between a first side and a second side thereof. The MLI feature is disposed over the first side. The method further includes forming a through via opening that extends through an insulation layer of the MLI feature and a depth into the device substrate. The depth is less than the first thickness and the through via opening has a first aspect ratio. The method further includes filling the through via opening with a sacrificial material. The method further includes removing a portion of the device substrate to reduce the first thickness to a second thickness. A portion of the sacrificial material is removed when the removing of the portion of the device substrate. The method further includes selectively removing the sacrificial material relative to the insulation layer and the device substrate. After selectively removing the sacrificial material, the through via opening has a second aspect ratio that is less than the first aspect ratio. The method further includes forming a through via in the through via opening having the second aspect ratio. The through via includes a barrier liner that wraps an electrically conductive plug, and the barrier liner and the insulation layer form a top surface of the workpiece. In some embodiments, the first side is a frontside of the device substrate, and the second side is a backside of the device substrate.

In some embodiments, forming the through via includes forming a barrier layer over the second side of the device substrate and forming a bulk layer over the barrier layer and the second side of the device substrate. The barrier layer partially fills the through via opening, and the bulk layer fills a remainder of the through via opening. A planarization process may be performed to remove a portion of the bulk layer and a portion of the barrier layer from over the second side of the device substrate, such that a remaining portion of the bulk layer forms the electrically conductive plug and a remaining portion of the barrier layer forms the barrier liner. In some embodiments, forming the barrier layer includes forming a dielectric layer over the second side of the device substrate and forming a barrier/seed layer over the dielectric layer. In such embodiments, a remaining portion of the dielectric layer forms a dielectric liner, a remaining portion of the barrier/seed layer forms a barrier/seed liner, and the barrier liner includes the dielectric liner and the barrier/seed liner. In some embodiments, forming the barrier layer includes forming the barrier/seed layer (i.e., the dielectric liner is omitted).

In some embodiments, a cleaning process is performed before forming the through via in the through via opening. In some embodiments, the method further includes forming a patterned metal layer over the MLI feature and the through via. The patterned metal layer includes a metal line over the through via. The barrier liner of the through via is between the metal line of the pattered metal layer and the electrically conductive plug of the through via.

In some embodiments, a top of the workpiece is formed by the insulation layer of the MLI feature, a bottom of the workpiece is formed by the second side of the device substrate, and forming the through via in the through via opening includes flipping over the workpiece before forming the through via in the through via opening. In some embodiments, the device substrate, the MLI feature, and the through via form a portion of a first chip, and the method further includes bonding the first chip to a second chip. The through via can provide an electrical connection between the first chip and the second chip.

An exemplary semiconductor structure includes a device substrate having a first side and a second side. An insulation layer is disposed over the first side of the device substrate. A through via extends through the insulation layer and through the device substrate from the first side to the second side. The through via includes a bulk layer disposed over a barrier layer. The barrier layer is between the bulk layer and the device substrate. The barrier layer is between the bulk layer and the insulation layer. The barrier layer has a first portion that forms a first sidewall of the through via, a second portion that forms a second sidewall of the through via, and a third portion that extends between the first portion and the second portion. The third portion is disposed in the insulation layer. In some embodiments, the first side is a frontside, the second side is a backside, and the third portion of the barrier layer forms a top of the through via.

In some embodiments, the barrier layer includes a dielectric liner and a metal-comprising liner, where the metal-comprising liner is between the bulk layer and the dielectric liner. In some embodiments, the barrier layer includes a metal-comprising liner without a dielectric liner. In some embodiments, the semiconductor structure further includes an interconnect structure disposed in the insulation layer and on the through via. The barrier layer is disposed between the interconnect structure and the bulk layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a through substrate via, the method comprising:
forming a trench that extends through an insulation layer and into a substrate, wherein the substrate has a first side and a second side, the insulation layer is disposed over the first side of the substrate, and the second side is opposite the first side;
filling the trench with a dielectric material;
performing a thinning process on the second side of the substrate, wherein the thinning process exposes the dielectric material; and
after performing the thinning process and removing the dielectric material from the trench, forming an electrically conductive structure in the trench, wherein the electrically conductive structure extends through the substrate from the first side to the second side.

2. The method of claim 1, wherein the forming the electrically conductive structure in the trench includes:
forming a barrier layer in the trench that forms a top and sidewalls of the electrically conductive structure; and
forming an electrically conductive layer over the barrier layer in the trench, wherein a portion of the barrier layer that forms the top of the electrically conductive structure is disposed in the insulation layer.

3. The method of claim 2, wherein the forming the barrier layer includes:
depositing a dielectric liner over the second side of the substrate, wherein the dielectric liner partially fills the trench; and
depositing a metal-comprising liner over the dielectric liner.

4. The method of claim 1, wherein:
the dielectric material filling the trench has a first thickness; and
the thinning process removes a portion of the dielectric material, thereby providing the dielectric material filling the trench with a second thickness that is less than the first thickness.

5. The method of claim 1, wherein the removing the dielectric material includes performing an etching process that selectively removes the dielectric material relative to the insulation layer and the substrate.

6. The method of claim 1, wherein:
the trench has a first aspect ratio; and
after the thinning process and the removing of the dielectric material, the trench has a second aspect ratio that is less than the first aspect ratio.

7. The method of claim 1, wherein:
the insulation layer and the substrate form a semiconductor structure; and
the method further includes flipping the semiconductor structure, such that the forming the electrically conductive structure in the trench includes depositing electrically conductive material over the second side of the substrate.

8. The method of claim 1, wherein
after the thinning process and the removing of the dielectric material, the trench has a top critical dimension in the insulation layer, a middle critical dimension proximate an interface of the insulation layer and the first side of the substrate, and a bottom critical dimension in the substrate; and
a ratio of the top critical dimension to the middle critical dimension to the bottom critical dimension is about 1:1:1 to about 4:2:1.

9. The method of claim 1, wherein the insulation layer and the substrate form a first semiconductor structure, the method further comprising bonding the first semiconductor structure to a second semiconductor structure, wherein the electrically conductive structure connects the first semiconductor structure and the second semiconductor structure.

10. A method comprising:
receiving a workpiece having a device substrate and a multilayer interconnect (MLI) feature, wherein the device substrate has a first thickness between a first side and a second side thereof and the MLI feature is disposed over the first side;
forming a through via opening that extends through an insulation layer of the MLI feature and a depth into the device substrate, wherein the depth is less than the first thickness and the through via opening has a first aspect ratio;
filling the through via opening with a sacrificial material;
removing a portion of the device substrate to reduce the first thickness to a second thickness, wherein the removing of the portion of the device substrate further includes removing a portion of the sacrificial material;
selectively removing the sacrificial material relative to the insulation layer and the device substrate, wherein the through via opening has a second aspect ratio after selectively removing the sacrificial material and the second aspect ratio is less than the first aspect ratio; and
forming a through via in the through via opening having the second aspect ratio, wherein the through via includes a barrier liner that wraps an electrically conductive plug and the barrier liner and the insulation layer form a top surface of the workpiece.

11. The method of claim 10, wherein the forming the through via includes:
forming a barrier layer over the second side of the device substrate, wherein the barrier layer partially fills the through via opening;
forming a bulk layer over the barrier layer and the second side of the device substrate, wherein the bulk layer fills a remainder of the through via opening; and
performing a planarization process to remove a portion of the bulk layer and a portion of the barrier layer from over the second side of the device substrate, wherein a remaining portion of the bulk layer forms the electrically conductive plug and a remaining portion of the barrier layer forms the barrier liner.

12. The method of claim 11, wherein the forming the barrier layer includes:
forming a dielectric layer over the second side of the device substrate; and
forming a barrier/seed layer over the dielectric layer, wherein a remaining portion of the dielectric layer forms a dielectric liner, a remaining portion of the barrier/seed layer forms a barrier/seed liner, and the barrier liner includes the dielectric liner and the barrier/seed liner.

13. The method of claim 10, wherein a top of the workpiece is formed by the insulation layer of the MLI feature, a bottom of the workpiece is formed by the second side of the device substrate, and the forming the through via in the through via opening includes flipping over the workpiece before forming the through via in the through via opening.

14. The method of claim 10, wherein the first side is a frontside of the device substrate and the second side is a backside of the device substrate.

15. The method of claim 10, wherein the device substrate, the MLI feature, and the through via form a portion of a first chip, the method further comprising bonding the first chip to a second chip, wherein the through via provides an electrical connection between the first chip and the second chip.

16. The method of claim 10, further comprising forming a patterned metal layer over the MLI feature and the through via, wherein the patterned metal layer includes a metal line disposed over the through via and the barrier liner of the through via is between the metal line of the pattered metal layer and the electrically conductive plug of the through via.

17. A semiconductor structure comprising:
a device substrate having a first side and a second side;
an insulation layer disposed over the first side of the device substrate; and
a through via that extends through the insulation layer and through the device substrate from the first side to the second side, wherein:
the through via includes a bulk layer disposed over a barrier layer,
the barrier layer is between the bulk layer and the device substrate,
the barrier layer is between the bulk layer and the insulation layer,
the barrier layer has a first portion that forms a first sidewall of the through via, a second portion that forms a second sidewall of the through via, and a third portion that extends between the first portion and the second portion, and
the third portion is disposed in the insulation layer.

18. The semiconductor structure of claim 17, wherein the first side is a frontside, the second side is a backside, and the third portion of the barrier layer forms a top of the through via.

19. The semiconductor structure of claim 17, wherein the barrier layer includes a dielectric liner and a metal-comprising liner, wherein the metal-comprising liner is between the bulk layer and the dielectric liner.

20. The semiconductor structure of claim 17, further comprising an interconnect structure disposed in the insulation layer and on the through via, wherein the barrier layer is disposed between the interconnect structure and the bulk layer.
